(19) United States
(12) Patent Application Publication
(10) Pub. No.: US 2012/0006379 A1
(43) Pub. Date: Jan. 12, 2012

(54) DYE-SENSITIZED SOLAR CELL MODULE

(75) Inventor: Miho SASAKI, Tokyo-to (JP)

(73) Assignee: DAI NIPPON PRINTING CO., LTD., Tokyo-to (JP)

(21) Appl. No.: 13/173,368

(22) Filed: Jun. 30, 2011

(30) Foreign Application Priority Data
Jul. 7, 2010 (JP) 2010-154636

(51) Int. Cl. H01L 31/042; H01L 31/0224

(52) U.S. Cl. 136/244; 438/73; 257/E31.124

(57) ABSTRACT

A main object of the present invention is to provide a high quality dye-sensitized solar cell module which prevents a discrepancy in the position of a pair of base materials, and does not easily allow the occurrence of connection failure or internal short circuit, and a method for producing a dye-sensitized solar cell module which allows easy production of the dye-sensitized solar cell module. To attain the object, the present invention discloses a dye-sensitized solar cell module comprising: a pair of resin substrates having flexibility, and two or more dye-sensitized solar cells formed between the pair of resin substrates, wherein a fixing member is disposed between adjacent dye-sensitized solar cells, and the fixing member is formed so as to penetrate through from an external side of one of the resin substrates to an external side of the other resin substrate.

### TECHNICAL FIELD

The present invention relates to a high quality dye-sensitized solar cell module which prevents a discrepancy in the position of a pair of base materials, and does not easily allow the occurrence of connection failure or internal short circuit, and a method for producing a dye-sensitized solar cell module which allows easy production of the dye-sensitized solar cell module.

### BACKGROUND ART

In recent years, environmental problems such as global warming which is considered to be attributable to an increase of carbon dioxide, have become more serious, and countermeasures against the problems are being provided worldwide. Among others, active research and development is being carried out in conjunction with solar cells that utilize solar light energy, as an energy source which is clean and places less burden on the environment. As the solar cells as such, single crystal silicon solar cells, polycrystalline silicon solar cells, amorphous silicon solar cells, compound semiconductor solar cells, and the like have already been put to practical use, but these solar cells have problems such as high production cost. Thus, attention has been paid to dye-sensitized solar cells as a class of solar cells which imposes less environmental burden and can reduce the production cost, and research and development thereof is underway.

In regard to the dye-sensitized solar cells, since this type of solar cells needs to provide larger output voltage in order to be put to practical use, attempts have been made to connect plural dye-sensitized solar cells into a dye-sensitized solar cell module.

As a method for forming such a dye-sensitized solar cell module, for example, a method of producing individual dye-sensitized solar cells, and then connecting each of the solar cells using wiring to obtain a dye-sensitized solar cell module, may be used. However, in this method, there is a need to provide wiring for each of the individual dye-sensitized solar cells, and thus, there is a problem that the fabrication process is complicated.

Therefore, a method has been attempted, in which plural dye-sensitized solar cells are formed between two sheets of base materials, and connection is made between the electrode layers of the individual dye-sensitized solar cells within the pair of base materials. An example of such a method may be a method in which an oxide semiconductor electrode layer, an electrolyte layer and a counter electrode layer that are used in each of the dye-sensitized solar cells, are formed such that the respective positions of formation are slightly shifted, to make the respective electrode layers of adjacent dye-sensitized solar cells face each other, and a metal paste is disposed between the mutually facing electrode layers, so as to connect between the electrode layers of the dye-sensitized solar cells.

Here, in regard to the dye-sensitized solar cell module, glass substrates have been traditionally used as the base material, but in recent years, investigations have been conducted on the use of a flexible substrate as the base material in the occasions where it is desirable to make the dye-sensitized solar cell module flexible. However, when the substrate having flexibility described above is used as the base material used in the dye-sensitized solar cell module, and the respective dye-sensitized solar cells are connected by the method of disposing a metal paste as described above, a discrepancy in the position of the substrates occurs as the substrates are bent, and the distance between the electrode layers of adjacent dye-sensitized solar cells may change. Therefore, a problem is posed that there is a possibility that the metal paste and the electrode layers may be separated apart, causing connection failure.

In regard to the problem described above, Japanese Patent Application Laid-Open (JP-A) No. 2007-299545 suggests a dye-sensitized solar cell module having a configuration such as presented in FIG. 17. As shown in FIG. 17, a dye-sensitized solar cell module 100 suggested in JP-A No. 2007-299545 has a glass substrate 101a, a resin substrate 101b, and plural dye-sensitized solar cells 110 that are formed between the glass substrate 101a and the resin substrate 101b. Furthermore, each of the dye-sensitized solar cells 110 comprises: an oxide semiconductor electrode layer including a first electrode layer 111 which is formed on the surface of the glass substrate 101a, and a porous layer 112 which is formed on the first electrode layer 111 and contains a dye-sensitizer-supported fine particle of a metal oxide semiconductor; a counter electrode layer including a second electrode layer 121 formed on the surface of the resin substrate 101b, and a catalyst layer 122 formed on the second electrode layer 121; and an electrolyte layer 103 provided between the porous layer 112 and the catalyst layer 122. Furthermore, dye-sensitized solar cells 110 that are formed at the edges of the dye-sensitized solar cell module 100 comprises sealing members 106.

In the dye-sensitized solar cell module 100 described in JP-A No. 2007-299545, the first electrode layers 111 and the second electrode layers 121 of adjacent dye-sensitized solar cells 110 are brought into contact with each other by disposing a pressing plate 150 which is provided with plural convex portions on the face, at the external side of the resin substrate 101b. The glass substrate 101a and the pressing plate 150 are fixed by a fixing frame 160 provided at the edges of the dye-sensitized solar cell module 100.

In the dye-sensitized solar cell module having the configuration described above, the electrode layers of adjacent dye-sensitized solar cells may be brought into contact by applying pressure between the electrode layers with the pressing plate. However, since the glass substrate and the pressing plate are fixed only by the fixing frame disposed at the edges of the dye-sensitized solar cell module, it is difficult to satisfactorily maintain the positions of the glass substrate and the resin substrate of the dye-sensitized solar cell module in a predefined positional relationship. Also, there is a problem that it is difficult to sufficiently prevent the connection failure caused by the discrepancy in the position of the pair of base materials.

It has been also investigated to use a metal layer having flexibility, such as a metal foil, as the base material for the dye-sensitized solar cell module. In the case of using the metal layer as the base material of a dye-sensitized solar cell module, it is possible to use the metal layer also as an electrode layer of the dye-sensitized solar cell. When the metal layer is used as the electrode layer, even in the case of making the dye-sensitized solar cell flexible and large in size, there is an advantage that current collection is satisfactorily achieved, or an advantage that burning at high temperature is made possible at the time of forming the dye-sensitive solar cell.

This metal layer may be suitably used as a base material of a dye-sensitized solar cell module in which plural dye-sensitized solar cells are formed on the same metal layer, and the respective dye-sensitized solar cells are connected in parallel by means of the metal layer.

However, when the metal layer is used as the base material of the dye-sensitized solar cell module, there is a problem that when the metal layer is bent, the electrode layers of the same dye-sensitized solar cells are brought into contact with each other, and internal short circuit occurs.

The occurrence of the internal short circuit is a problem that is not limited to the above-mentioned dye-sensitized solar cell module having a metal layer, but may also occur in a dye-sensitized solar cell module in which plural dye-sensitized solar cells are formed on the same electrode layer, and the respective dye-sensitized solar cells are connected in parallel by means of the electrode layer.

Therefore, when a resin substrate having flexibility is used as the base material of the dye-sensitized solar cell module, a method for preventing the discrepancy in the position of the substrates, and easily connecting the electrode layers of the respective dye-sensitized solar cells without causing connection failure, is demanded.

Furthermore, when a metal layer having flexibility is used for the base material of the dye-sensitized solar cell module, a method for preventing the occurrence of internal short circuit is demanded.

### SUMMARY OF INVENTION

### Technical Problem

An object of the present invention is to provide a high-quality dye-sensitized solar cell module which prevents the occurrence of a discrepancy in the position of a pair of base materials so that connection failure or internal short circuit does not easily occur, and a method for producing a dye-sensitized solar cell module, which facilitates the production of the aforementioned dye-sensitized solar cell module.

### Solution to Problem

The present invention aims to solve the problem described above by providing a dye-sensitized solar cell module comprising: a pair of resin substrates having flexibility; and two or more dye-sensitized solar cells formed between the pair of resin substrates, wherein a fixing member is disposed between adjacent dye-sensitized solar cells and the fixing member is formed so as to penetrate through from an external side of one of the resin substrates to an external side of the other resin substrate.

According to the present invention, when the fixing member is formed so as to penetrate through from the external side of one of the resin substrates to the external side of the other resin substrate, and is disposed between the adjacent dye-sensitized solar cells, even if the dye-sensitized solar cell module is bent many times due to the use for a long time period, the pair of resin substrates can be maintained in a predefined positional relationship. Thereby, a dye-sensitized solar cell module having excellent durability may be obtained.

In the present invention, preferably, each of the dye-sensitized solar cells comprises: an oxide semiconductor electrode layer which includes a first electrode layer formed on a surface of one of the resin substrates, and a porous layer formed on the first electrode layer and containing a dye-sensitizer-supported fine particle of a metal oxide semiconductor; a counter electrode layer which includes a second electrode layer formed on a surface of the other resin substrate, and a catalyst layer formed on the second electrode layer; and an electrolyte layer provided between the porous layer and the catalyst layer and containing a redox couple, wherein the adjacent dye-sensitized solar cells are formed such that the first electrode layer or the second electrode layer of one of the dye-sensitized solar cells formed on one of the resin substrates, and the first electrode layer or the second electrode layer of the other dye-sensitized solar cell formed on the other resin substrate face each other at least partially, and the fixing member is formed between the first electrode layers, between the first electrode layer and the second electrode layer, or between the second electrode layers of the adjacent dye-sensitized solar cells, and fixes positions of the pair of resin substrates such that the electrode layers are in a positional relationship allowing connection between the electrode layers. Since the positions of the pair of resin substrates can be securely fixed in a positional relationship in which the electrode layers of the adjacent dye-sensitized solar cells can be connected to each other, connection between the electrode layers is easily achieved, and a dye-sensitized solar cell module having no connection defects can be obtained.

Furthermore, in the present invention, preferably, among the adjacent dye-sensitized solar cells, the first electrode layer of one of the dye-sensitized solar cells is formed on the surface of one of the resin substrates, while the second electrode layer of the other dye-sensitized solar cell is formed on the surface of the other resin substrate, and the fixing member fixes the positions of the pair of resin substrates such that the first electrode layer of one of the dye-sensitized solar cells and the second electrode layer of the other dye-sensitized solar cell are in a positional relationship allowing connection between the electrode layers. When the dye-sensitized solar cell module is constructed to have a configuration such as described above, the production of a dye-sensitized solar cell module having a series structure is facilitated.

In the present invention, the fixing member is preferably electrically conductive. When the fixing member is electrically conductive, the electrode layers of the adjacent dye-sensitized solar cells can be connected using the fixing member.

The present invention provides a dye-sensitized solar cell module comprising two or more dye-sensitized solar cells formed therein, each of the dye-sensitized solar cell having: a metal layer having flexibility; a transparent resin substrate having flexibility, and carrying an electrode layer having transparency formed on one surface of the transparent resin substrate; a porous layer formed in a pattern on a surface of the metal layer or a surface of the electrode layer having transparency, and containing a dye-sensitizer-supported fine particle of a metal oxide semiconductor; a catalyst layer formed on the surface of the metal layer or the surface of the electrode layer having transparency, where the porous layer is not formed; and an electrolyte layer provided between the porous layer and the catalyst layer and containing a redox couple, wherein an fixing member having insulating properties is disposed between adjacent dye-sensitized solar cells and the fixing member is formed so as to penetrate through from an external side of the metal layer to an external side of the transparent resin substrate.

According to the present invention, when the fixing member is formed so as to penetrate through from the external side of the metal layer to the external side of the transparent resin substrate, even if the dye-sensitized solar cell module is bent many times due to the use for a long time period, the metal layer and the transparent resin substrate can be maintained in a predefined positional relationship. Thereby, a dye-sensitized solar cell module having excellent durability can be obtained. Furthermore, when the metal layer and the transparent resin substrate are fixed by the fixing member, internal short circuit can be prevented.

In the present invention, a thickness of a portion fixed by the fixing member is preferably smaller than a thickness of a portion where the dye-sensitized solar cell is formed. This is because when the fixing member is disposed such that the dye-sensitized solar cell module of the present invention attains the configuration described above, the distance between the pair of resin substrates, or the distance between the metal layer and the transparent resin substrate can be shortened, and the connection between the electrode layers of the adjacent dye-sensitized solar cells can be made more secure.

The present invention provides a method for producing a dye-sensitized solar cell module comprising a pair of resin substrates having flexibility, and at least two dye-sensitized solar cells formed between the pair of resin substrates, the method comprising steps of: forming at least two dye-sensitized solar cells, each having an oxide semiconductor electrode layer which includes a first electrode layer formed on a surface of one of the resin substrates, and a porous layer formed on the first electrode layer and containing a dye-sensitizer-supported fine particle of a metal oxide semiconductor, a counter electrode layer which includes a second electrode layer formed on a surface of the other resin substrate, and a catalyst layer formed on the second electrode layer, and an electrolyte layer provided between the porous layer and the catalyst layer and containing a redox couple; and disposing a fixing member between adjacent dye-sensitized solar cells by forming the fixing member so as to penetrate through from an external side of one of the resin substrates to an external side of the other resin substrate.

According to the present invention, when the method includes fixing member disposing step of forming two or more dye-sensitized solar cells between the pair of resin substrates, and then providing the fixing member, the pair of resin substrates can be fixed such that the electrode layers are disposed in a predefined positional relationship. Therefore, a dye-sensitized solar cell module having less connection failure and having excellent durability can be easily produced.

The present invention provides a method for producing a dye-sensitized solar cell module, the method comprising steps of: forming two or more dye-sensitized solar cells, each having a metal layer having flexibility, a transparent resin substrate having flexibility, and carrying an electrode layer having transparency formed on one surface of the transparent resin substrate, a porous layer formed in a pattern on a surface of the metal layer or a surface of the electrode layer having transparency, and containing a dye-sensitizer-supported fine particle of a metal oxide semiconductor, a catalyst layer formed on the surface of the metal layer or the surface of the electrode layer having transparency, where the porous layer is not formed, and an electrolyte layer provided between the porous layer and the catalyst layer and containing a redox couple; and disposing a fixing member having insulating properties between adjacent dye-sensitized solar cells by forming the fixing member so as to penetrate through from an external side of the metal layer to an external side of the transparent resin substrate.

According to the present invention, when the method includes fixing member disposing step, the fixing member can be disposed between the adjacent dye-sensitized solar cells. Therefore, the occurrence of internal short circuit can be prevented, and a dye-sensitized solar cell module having excellent durability can be easily produced.

### Advantageous Effects of Invention

By having the fixing member, the dye-sensitized solar cell module of the present invention can maintain the pair of base materials in a predefined positional relationship, even if the dye-sensitized solar cell module is bent many times due to the use for a long time period. Thereby, deterioration due to the discrepancy in the position of the pair of base materials can be prevented, and a dye-sensitized solar cell module having excellent durability can be obtained. Furthermore, according to the present invention, since the dye-sensitized solar cell module can maintain the pair of base materials in a predefined positional relationship by having the fixing member, the connection failure between the electrode layers of the adjacent dye-sensitized solar cells in the dye-sensitized solar cell module, or the occurrence of internal short circuit of the dye-sensitized solar cell module can be prevented.

### BRIEF DESCRIPTION OF DRAWINGS

FIG. 1 is a schematic cross-sectional diagram showing an example of the dye-sensitized solar cell module according to an embodiment of the present invention.

FIG. 2 is a schematic cross-sectional diagram showing another example of the dye-sensitized solar cell module according to the embodiment of the present invention.

FIGS. 3A and 3B are each a schematic cross-sectional diagram showing still another example of the dye-sensitized solar cell module according to the embodiment of the present invention.

FIGS. 4A and 4B are each a schematic cross-sectional diagram showing yet another example of the dye-sensitized solar cell module according to the embodiment of the present invention.

FIGS. 5A and 5B are each a schematic cross-sectional diagram showing yet another example of the dye-sensitized solar cell module according to the embodiment of the present invention.

FIG. 6 is a schematic cross-sectional diagram showing yet another example of the dye-sensitized solar cell module according to the embodiment of the present invention.

FIG. 7 is a schematic cross-sectional diagram showing still another example of the dye-sensitized solar cell module according to the embodiment of the present invention.

FIGS. 8A and 8B are each a schematic diagram showing an example of the dye-sensitized solar cell module according to another embodiment of the present invention.

FIG. 9 is a schematic cross-sectional diagram showing another example of the dye-sensitized solar cell module according to the embodiment of the present invention.

FIG. 10 is a schematic diagram showing still another example of the dye-sensitized solar cell module according to the embodiment of the present invention.

FIG. 11 is a schematic cross-sectional diagram showing yet another example of the dye-sensitized solar cell module according to the embodiment of the present invention.

FIG. 12 is a schematic cross-sectional diagram showing yet another example of the dye-sensitized solar cell module according to the embodiment of the present invention.

FIG. 13 is a schematic cross-sectional diagram showing still another example of the dye-sensitized solar cell module according to the embodiment of the present invention.

FIG. 14 is a schematic cross-sectional diagram showing yet another example of the dye-sensitized solar cell module according to the embodiment of the present invention.

FIGS. 15A to 15C area process diagram showing an example of the method for producing a dye-sensitized solar cell module according to another embodiment of the present invention.

FIGS. 16A to 16C are a process diagram showing another example of the method for producing a dye-sensitized solar cell module according to the embodiment of the present invention.

FIG. 17 is a schematic cross-sectional diagram showing an exemplary dye-sensitized solar cell module.

### DESCRIPTION OF EMBODIMENTS

Hereinafter, the dye-sensitized solar cell module of the present invention, and the method for producing a dye-sensitized solar cell module, which is useful for the production of the dye-sensitized solar cell module of the present invention, will be described in detail.

### A. Dye-Sensitized Solar Cell Module

The dye-sensitized solar cell module of the present invention uses substrates having flexibility as a pair of base materials, and is characterized in that the pair of base materials are fixed in a predefined positional relationship, by forming a fixing member which penetrates through from the external side of one base material to the external side of the other base material. Such a dye-sensitized solar cell module may be represented in two embodiments, such as an embodiment in which the pair of base materials is constituted of a pair of resin substrates (hereinafter, referred to as Embodiment 1), and an embodiment in which the pair of base materials is constituted of a metal layer and a transparent resin substrate (hereinafter, referred to as Embodiment 2). Each of the embodiments will be described in the following.

### I. Dye-Sensitized Solar Cell Module of Embodiment 1

The dye-sensitized solar cell module according to Embodiment 1 of the present invention will be described.

The dye-sensitized solar cell module of the present embodiment comprises: a pair of resin substrates having flexibility, and two or more dye-sensitized solar cells formed between the pair of resin substrates, wherein a fixing member is disposed between adjacent dye-sensitized solar cells and the fixing member is formed so as to penetrate through from an external side of one of the resin substrates to an external side of the other resin substrate.

Here, each of the dye-sensitized solar cells comprises an oxide semiconductor electrode layer which includes a first electrode layer formed on a surface of one of the resin substrates, and a porous layer formed on the first electrode layer and containing a dye-sensitizer-supported fine particle of a metal oxide semiconductor; a counter electrode layer which includes a second electrode layer formed on a surface of the other resin substrate, and a catalyst layer formed on the second electrode layer; and an electrolyte layer provided between the porous layer and the catalyst layer and containing a redox couple.

In the following description, when the first electrode layer and the second electrode layer are described collectively, the layers may be simply referred to as electrode layers.

Here, since a dye-sensitized solar cell used in a general dye-sensitized solar cell module needs to receive sunlight through at least one of the oxide semiconductor electrode layer side and the counter electrode layer side, in the present embodiment, at least one of the pair of resin substrates is composed of a transparent resin substrate, and the electrode layer formed on the transparent resin substrate is composed of an electrode layer having transparency.

According to the present embodiment, since the fixing member is formed so as to penetrate through from the external side of one of the resin substrates to the external side of the other resin substrate, and is disposed between the adjacent dye-sensitized solar cells, even if the dye-sensitized solar cell module is bent many times due to the use for a long time period, the pair of resin substrates can be maintained in a predefined positional relationship. Thereby, deterioration due to a discrepancy in the position of the pair of resin substrates can be prevented, and therefore, a dye-sensitized solar cell module having excellent durability may be obtained.

An important feature of the dye-sensitized solar cell module of the present embodiment lies in that the dye-sensitized solar cell module has the fixing member described above. Furthermore, there are no particular limitations on the fixing member, as long as the fixing member is disposed between the adjacent dye-sensitized solar cells and is formed so as to penetrate through from the external side of one of the resin substrates to the external side of the other resin substrate.

According to the present embodiment, among others, it is preferable that the fixing member be disposed between the first electrodes, between the first electrode and the second electrode, or between the second electrodes, of adjacent dye-sensitized solar cells, and fix the pair of resin substrates such that these electrode layers are in a positional relationship allowing connection between the electrode layers. Thereby, the electrode layers of the adjacent dye-sensitized solar cells can be securely fixed in a positional relationship allowing connection between the electrode layers, and therefore, a dye-sensitized solar cell module which allows easy connection between the electrode layers and is free from connection defects, can be obtained.

An example of the dye-sensitized solar cell module having a fixing member such as described above may have the following configurations. The configurations of the dye-sensitized solar cell module will be described below with reference to the attached drawings.

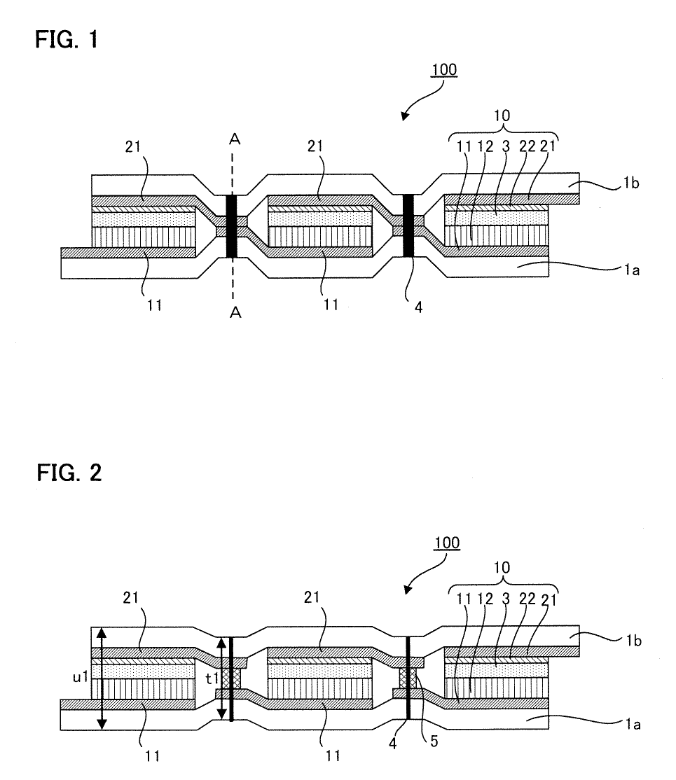

FIG. 1 is a schematic cross-sectional diagram showing a dye-sensitized solar cell module according to an embodiment of the present invention. As shown in FIG. 1, the dye-sensitized solar cell module 100 of the present embodiment comprises a pair of a resin substrate 1a and a resin substrate 1b, both having flexibility, and at least two dye-sensitized solar cells 10 formed between the resin substrate 1a and the resin substrate 1b (in FIG. 1, three dye-sensitized solar cells 10). Furthermore, each of the dye-sensitized solar cells 10 comprises an oxide semiconductor electrode layer which includes a first electrode 11 formed on the surface of the resin substrate 1a, and a porous layer 12 formed on the first electrode layer 11 and containing a dye-sensitizer-supported fine particle of a metal oxide semiconductor; a counter electrode layer which includes a second electrode layer 21 formed on the surface of the resin substrate 1b, and a catalyst layer 22 formed on the second electrode layer 21; and an electrolyte layer 3 provided between the porous layer 12 and the catalyst layer 22 and containing a redox couple.

Furthermore, as shown in FIG. 1, a fixing member 4 used in the present embodiment is intended to fix the positions of the resin substrate 1a and the resin substrate 1b, such that the first electrode layer 11 and the second electrode layer 21 facing each other are in a positional relationship allowing connection between the electrode layers, and the fixing member 4 is formed so as to penetrate through from the external side of the resin substrate 1a to the external side of the resin substrate 1b. In addition, FIG. 1 presents an example in which the electrolyte layer 3 is a solid electrolyte layer. Furthermore, FIG. 1 presents an example in which the resin substrate 1a and the resin substrate 1b are both transparent resin substrates, and the first electrode layer 11 and the second electrode layer 21 are both electrode layers having transparency.

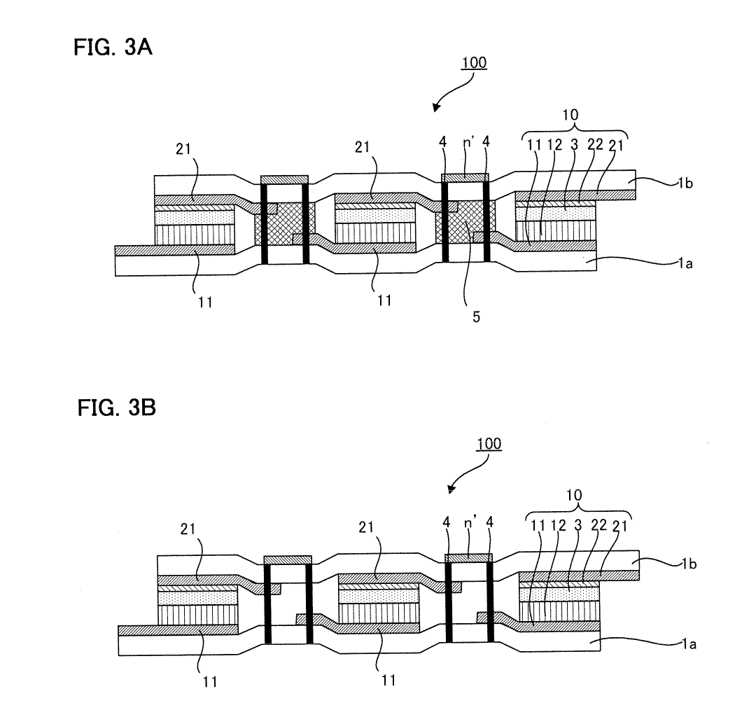

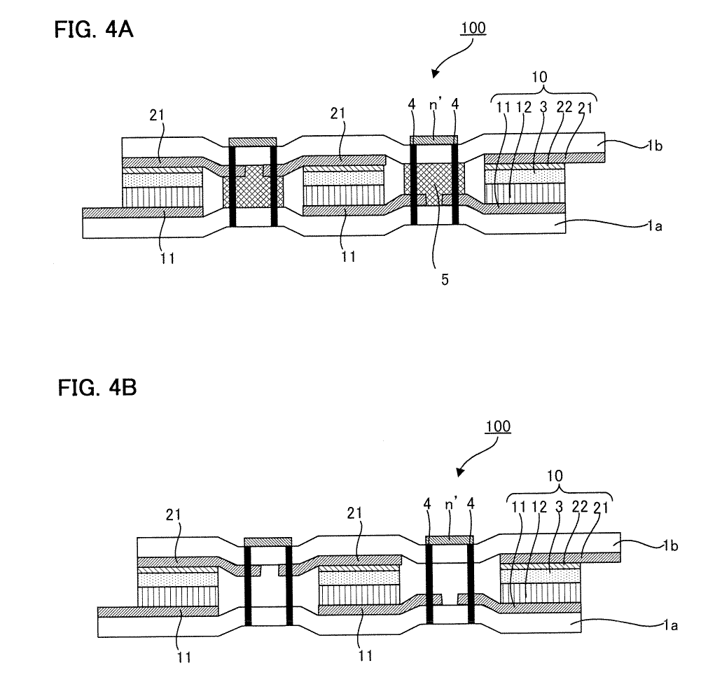

According to the present embodiment, the state in which “connection can be achieved between the electrode layers of adjacent dye-sensitized solar cells” refers to: a state in which, as shown in FIG. 1, the electrode layers are brought into contact to be connected to each other; a state in which, as shown in FIG. 2, FIG. 3A and FIG. 4A, the electrode layers of adjacent dye-sensitized solar cells 10 are connected, with a conductive material 5 interposed therebetween; and a state in which, as shown in FIG. 3B and FIG. 4B, the electrode layers of adjacent dye-sensitized solar cells 10 are connected by using a conductive fixing member 4. In addition, as shown in FIG. 2, FIG. 3A and FIG. 4A, in the case of achieving connection by interposing a conductive material 5 between the electrode layers of adjacent dye-sensitized solar cells 10, connection may also be achieved by further using a fixing member 4 which is electrically conductive, and thereby using the conductive material 5 and the conductive fixing member 4 in combination.

Furthermore, in the case of achieving connection between the electrode layers of adjacent dye-sensitized solar cells 10 using a conductive fixing member, as shown in FIGS. 3 4, a fixing member 4 having an external linkage fixing unit n′ which is electrically conductive, may be used. The external linkage fixing unit will be described later, and an explanation thereof will not be given here.

According to the present embodiment of the invention, as shown in FIG. 1 and FIG. 2, the fixing member 4 may be disposed such that connection can be achieved between the electrode layers of adjacent dye-sensitized solar cells 10 that are formed so as to at least partially face each other. Alternately, as shown in FIGS. 3 4, the fixing member 4 may be disposed such that connection can be achieved between the electrode layers of adjacent dye-sensitized solar cells 10 that are formed apart from each other. In the case of disposing the fixing member 4 such that connection can be achieved between the electrode layers of adjacent dye-sensitized solar cells 10 that are formed apart from each other, as shown in FIGS. 3A and 3B, the fixing member 4 may be disposed such that connection can be achieved between electrode layers that are respectively formed on the surfaces of different resin substrates, or as shown in FIGS. 4A and 4B, the fixing member 4 may be disposed such that connection can be achieved between electrode layers that are formed on the surface of the same resin substrate.

FIG. 2 to FIG. 4 are all schematic cross-sectional diagrams showing different examples of the dye-sensitized solar cell module of the present embodiment. The reference numerals that are not described herein have the same meanings as the reference numerals described in conjunction with FIG. 1, and further description will not be repeated here.

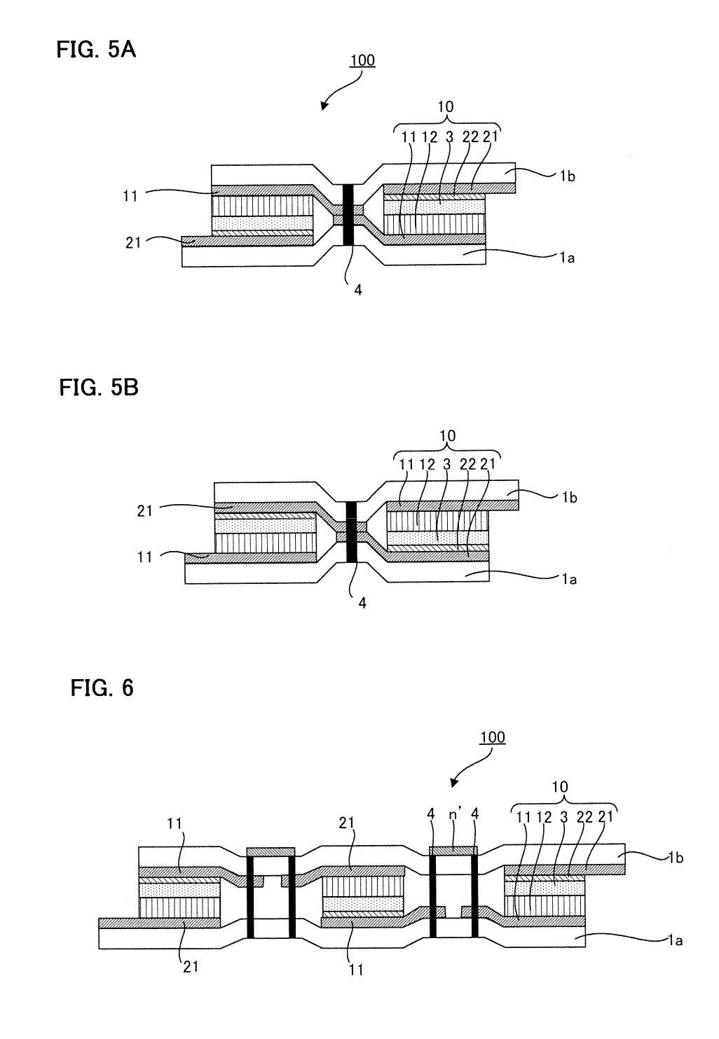

Furthermore, FIG. 1 to FIG. 3 all present examples in which the fixing member 4 is disposed such that connection can be achieved between the first electrode layer 11 formed on the surface of the resin substrate 1a, and the second electrode layer 21 formed on the surface of the resin substrate 1b. In addition to this, for example, as shown in FIG. 5A, the fixing member 4 may also be disposed such that connection can be achieved between the first electrode layer 11 formed on the surface of the resin substrate 1a, and the first electrode layer 11 formed on the surface of the resin substrate 1b. Alternately, for example, as shown in FIG. 5B, the fixing member 4 may also be disposed such that connection can be achieved between the second electrode layer 21 formed on the surface of the resin substrate 1a, and the second electrode layer 21 formed on the surface of the resin substrate 1b. FIGS. 5A and 5B are each a schematic cross-sectional diagram showing another example of the dye-sensitized solar cell module of the present embodiment. The reference numerals that are not described herein have the same meanings as the reference numerals described in conjunction with FIG. 1, and further description will not be repeated here.

FIGS. 4A and 4B present an example in which the fixing member 4 is disposed such that connection can be achieved between the first electrode layers 11 formed on the surface of the resin substrate 1a, or between the second electrode layers 21 formed on the surface of the resin substrate 1b. In addition to this, as shown in FIG. 6, the fixing member 4 may be disposed such that connection can be achieved between the first electrode layer 11 and the second electrode layer 21 that are formed on the surface of the resin substrate 1a or on the surface of the resin substrate 1b. FIG. 6 is a schematic cross-sectional diagram showing another example of the dye-sensitized solar cell module of the present embodiment. The reference numerals that are not described herein have the same meanings as the reference numerals described in conjunction with FIGS. 4A and 4B, and further description will not be repeated here.

Here, typically, in order to form the dye-sensitized solar cell during the production of the dye-sensitized solar cell module, it is preferable to form only the first electrode layer or only the second electrode layer, on the same resin substrate, because the formation process can be made easier. Therefore, it is also preferable for the dye-sensitized solar cell module to have only the first electrode layer or only the second electrode layer, on one of the resin substrates.

Therefore, when the fixing member is disposed such that connection can be achieved between the electrode layers formed on the surfaces of different resin substrates, it is preferable that the fixing member be disposed so that connection can be achieved between the first electrode layer and the second electrode layer. Furthermore, when the fixing member is disposed such that connection can be achieved between the electrode layers formed on the surface of the same resin substrate, it is preferable that the fixing member be disposed such that connection can be achieved between the first electrode layers or between the second electrode layers.

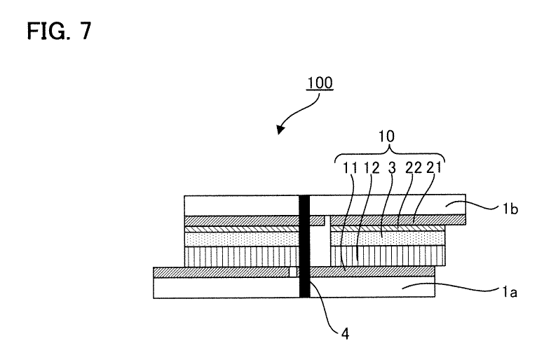

In regard to the position at which the fixing member is disposed, there are no particular limitations as long as it is possible to fix the pair of resin substrates such that the electrode layers of adjacent dye-sensitized solar cells are in a positional relationship allowing connection between the electrode layers. For example, as shown in FIG. 7, the fixing member 4 maybe disposed at a position at which the fixing member 4 is brought into contact with the porous layer 12, the electrolyte layer 3 or the like of the dye-sensitized solar cell 10. FIG. 7 is a schematic cross-sectional diagram showing another example of the dye-sensitized solar cell module of the present embodiment. The reference numerals that are not described herein have the same meanings as the reference numerals described in conjunction with FIG. 1, and further description will not be repeated here.

According to the present embodiment, even in the case where the fixing member is electrically conductive, the fixing member can be disposed at a position at which the fixing member is brought into contact with the porous layer or the electrolyte layer of the dye-sensitized solar cell.

Here, generally, in a dye-sensitized solar cell, when the first electrode layer and the second electrode layer of the same dye-sensitized solar cell are brought into contact, internal short circuit occurs. However, the fixing member of the present embodiment fixes the position of a pair of resin substrates such that connection can be achieved between the electrode layers of different dye-sensitized solar cells. Therefore, even if the porous layer, the electrolyte layer or the like of one of the dye-sensitized solar cells among adjacent dye-sensitized solar cells is brought into contact with the fixing member, when the first electrode layer and the second electrode layer within the same dye-sensitized solar cell are not in contact, internal short circuit does not occur.

According to the present embodiment, inter alia, it is preferable that the fixing member be disposed in a region where the electrolyte layer is not present. It is because, since the dye-sensitized solar cell uses an electrolyte layer containing iodide ions in some cases, when the fixing member and the solid electrolyte layer are brought into contact, there is a risk that the fixing member may be corroded by the iodide ions.

There are no particular limitations on the placement of the fixing member according to the present embodiment, as long as the fixing member can be disposed so as to penetrate through from the external side of one of the resin substrates to the external side of the other resin substrate. Among others, in regard to the placement of the fixing member, it is preferable that the fixing member be disposed in the dye-sensitized solar cell module of the present embodiment such that the thickness of the portion fixed by the fixing member is smaller than the thickness of the portion where the dye-sensitized solar cell is formed. This is because the distance between the electrode layers of adjacent dye-sensitized solar cells can be shortened thereby, and thus the connection between the electrode layers can be made more secure. Here, the “thickness of the portion fixed by the fixing member” according to the present embodiment refers to the distance t1 from the external surface of the resin substrate 1a to the external surface of the resin substrate 1b at the portion where the fixing member 4 is disposed, as shown in FIG. 2. The “thickness of the portion where the dye-sensitized solar cell is formed” refers to the distance ul from the external surface of the resin substrate 1a to the external surface of the resin substrate 1b at the portion where the dye-sensitized solar cell 10 is formed, as shown in FIG. 2.

In regard to the configuration of the dye-sensitized solar cell module according to the present embodiment, among the configurations described above, preferred is a configuration in which the adjacent dye-sensitized solar cells are formed such that the first electrode layer or the second electrode layer of the dye-sensitized solar cell formed on one of the resin substrates, and the first electrode layer or the second electrode layer of the dye-sensitized solar cell formed on the other resin substrate are disposed to at least partially face each other. The reason for this is as follows. The dye-sensitized solar cell module having a configuration described above is prone to the connection failure between the electrode layers of adjacent dye-sensitized solar cells due to the discrepancy in the position of a pair of resin substrates. Therefore, when the fixing member is disposed in the dye-sensitized solar cell module having the configuration described above, significant effects of the fixing member can be manifested.

Furthermore, when the ease of the production process is taken into consideration, in regard to the configuration described, it is more preferred that the first electrode layer 11 of one of the dye-sensitized solar cells among the adjacent dye-sensitized solar cells is formed on the surface of one of the resin substrates 1a, while the second electrode layer 21 of the other dye-sensitized solar cell is formed on the surface of the other resin substrate 1b, and the fixing member 4 fixes the pair of resin substrates so that the first electrode layer 11 and the second electrode layer 21 can be connected, as shown in FIG. 1 and FIG. 2. Furthermore, according to the present embodiment, it is preferable that a conductive material 5 be interposed between the first electrode layer 11 and the second electrode layer 21, as shown in FIG. 2. It is because when the construction described above is used, connection can be made more suitably between the first electrode layer and the second electrode layer.

In the description given above, an embodiment of the dye-sensitized solar cell module has been described, in which the fixing member fixes a pair of resin substrates such that the electrode layers of adjacent dye-sensitized solar cells are in a positional relationship allowing connection between the electrode layers. However, with regard to the dye-sensitized solar cell module of the present embodiment, an embodiment other than the embodiment described above may be such that plural dye-sensitized solar cells are formed on the first electrode layer and the second electrode layer formed on the entire surface of the resin substrates, and the respective dye-sensitized solar cells are connected in series by the first electrode layer and the second electrode layer. The placement of the fixing member and the like of the dye-sensitized solar cell module of such an embodiment will be described in the section “II. Dye-sensitized solar cell module of Embodiment 2”, and therefore, explanation thereof will not be given here.

The respective constructions used in the dye-sensitized solar cell module of the present embodiment will be described below.

1. Fixing Member

The fixing member used in the present embodiment is a member that is disposed between adjacent dye-sensitized solar cells, and is formed so as to penetrate through from the external side of one of the resin substrates to the external side of the other resin substrate.

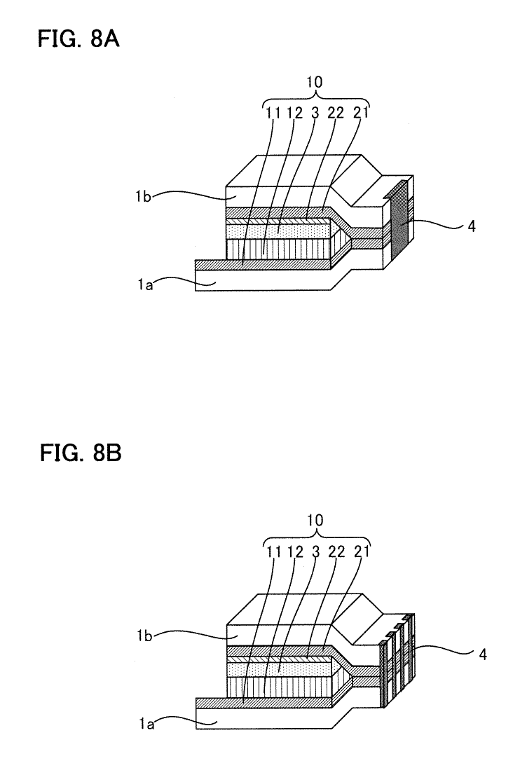

In regard to such a fixing member, it is acceptable that at least one fixing member be formed between the adjacent dye-sensitized solar cells, but it is preferable that two or more fixing members be formed (see, for example, FIG. 8B). When a plural number of the fixing members are formed, the pair of resin substrates can be fixed more suitably. Therefore, even if the fixing member is bent many times due to the use for a long time period, deterioration due to the discrepancy in the position of a pair of resin substrates can be prevented.

Furthermore, there are no particular limitations on the fixing member used in the present embodiment as long as the fixing member can be disposed between adjacent dye-sensitized solar cells, and can be formed so as to penetrate through from the external side of one of the resin substrates to the external side of the other resin substrate. However, it is more preferable that the fixing member be capable of fixing the pair of resin substrates such that the electrode layers of the adjacent dye-sensitized solar cells are in a positional relationship allowing connection between the electrode layers. Since the positions of the pair of resin substrates can be securely fixed in a positional relationship that allows the electrode layers of the adjacent dye-sensitized solar cells to be connected with each other, a dye-sensitized solar cell module which is free from connection defects can be obtained.

Furthermore, the fixing member is not particularly limited as long as it may be provided between the electrode layers of at least a group of adjacent dye-sensitized solar cells in the dye-sensitized solar cell module of the present embodiment, and the fixing member can be provided between the electrode layers of any adjacent dye-sensitized solar cells. According to the present embodiment, among others, it is preferable that the fixing member be provided between the electrode layers of all adjacent dye-sensitized solar cells in the dye-sensitized solar cell module. This is because connection failure between the respective electrode layers can be suppressed thereby, and thus, a dye-sensitized solar cell module having a high output voltage can be obtained. Furthermore, since the pair of resin substrates can be more firmly fixed by providing fixing members for all the dye-sensitized solar cells, the dye-sensitized solar cell module of the present embodiment can acquire superior durability.

There are no particular limitations on the fixing member as long as it is capable of fixing the positions of the pair of resin substrates such that the electrode layers of the adjacent dye-sensitized solar cells are in a positional relationship allowing connection between the electrode layers, and the fixing member may be an electrically conductive member or may be a non-conductive member.

When the fixing member is an electrically conductive member, the material for the fixing member may be a metal. There are no particular limitations on the metal as long as the metal has rigidity, and specific examples include stainless steel, copper, aluminum, nickel, iron, silver, lead, zinc, titanium, chromium, tungsten, gold, platinum, and alloys thereof. According to the present embodiment, even among the metals described above, it is preferable to use a metal which has high resistance to the corrosion due to iodide ions. It is because, since the electrolyte layer carried by the dye-sensitized solar cell may contain iodide ions in some cases, when the metal used for the fixing member is selected to be a metal having high resistance to the corrosion due to iodide ions, deterioration over time of the dye-sensitized solar cell module of the present embodiment can be prevented.

Examples of the material used in the case where the fixing member is a non-conductive member, include resins, glass, and metal oxides. Furthermore, a fixing member produced by coating the surface of a conductive metal or the like with an insulating film, can also be used as a non-conductive fixing member.

According to the present embodiment, it is more preferable that the fixing member be electrically conductive. When the fixing member is an electrically conductive member, the electrode layers of the adjacent dye-sensitized solar cells can also be connected by the fixing member, and therefore, connection failure can be more effectively prevented.

There are no particular limitations on the shape of the fixing member of the present embodiment, as long as the shape is capable of fixing the positions of the pair of resin substrates such that the electrode layers of the adjacent dye-sensitized solar cells are in a positional relationship allowing connection between the electrode layers. For example, as shown in FIG. 8A, a planar-shaped fixing member 4 may be used, or as shown in FIG. 8B, a pillar-shaped fixing member 4 may also be used. However, the planar-shaped fixing member 4 is more preferred. When the fixing member has a planar shape, the pair of resin substrates can be fixed more firmly, and the discrepancy in the position of the pair of resin substrates can be more suitably prevented. Here, FIGS. 8A and 8B are each a schematic diagram showing the view of the A-A cross-section of the dye-sensitized solar cell module shown in FIG. 1, from an oblique direction. The reference numerals that are not described with regard to FIGS. 8A and 8B have the same meanings as the reference numerals described in conjunction with FIG. 1, and further description will not be repeated here.

Specific examples of the shape of the fixing member include a plate shape, a pillar shape, and a wire shape. When the fixing member is pillar-shaped or wire-shaped, examples of the cross-sectional shape include rectangular, circular, elliptical, and polygonal shapes.

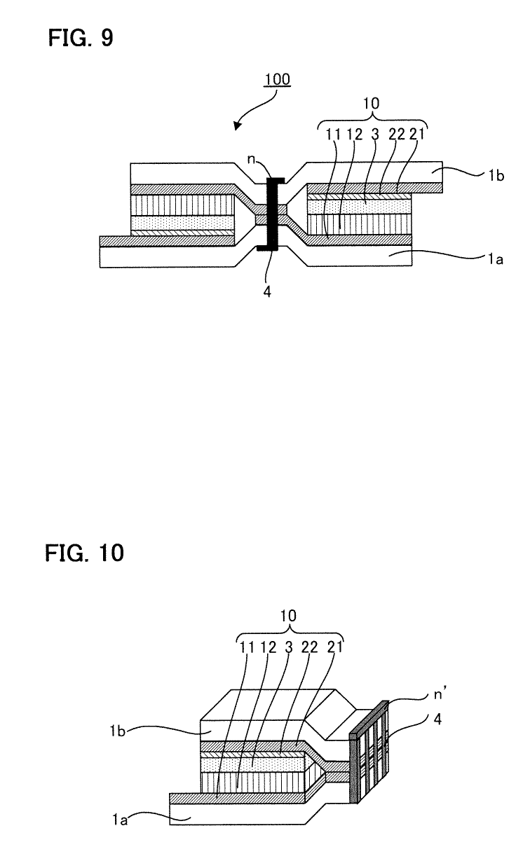

For the fixing member used in the present embodiment, as shown in FIG. 9, it is preferable that the fixing member 4 have a fixing unit n for preventing the fixing member from falling out from the dye-sensitized solar cell module 100, at an edge of the fixing member 4. This is because when the fixing member has a fixing unit at the edge of the fixing member, the positions of the pair of resin substrates can be more suitably fixed. FIG. 9 presents an example of the fixing member 4 having fixing units n at both edges; however, although not depicted in the diagram, it is still acceptable to provide the fixing unit at any one of the edges of the fixing member. FIG. 9 is a schematic cross-sectional diagram showing another example of the dye-sensitized solar cell module of the present embodiment, and the reference numerals that are not described herein have the same meanings as the reference numerals described in conjunction with FIG. 1. Thus, further description will not be repeated here.

In regard to the fixing unit, as shown in FIG. 9, the fixing unit may fix individual fixing members 4, or as shown in FIG. 3, FIG. 4, FIG. 6 and FIG. 10, the fixing unit may be an external linkage fixing unit n′ which fixes plural fixing members 4 by linking the fixing members on the external side of one of the resin substrates (in FIG. 3, FIG. 4, FIG. 6 and FIG. 10, the resin substrate 1b).

According to the present embodiment, in the case of fixing plural fixing members formed among a group of adjacent dye-sensitized solar cells, it is preferable to use the external linkage fixing unit. This is because fixing can be easily achieved as compared with the case of providing fixing units for individual fixing members. It is also because, as shown in FIG. 10, when an external linkage fixing unit n′ and fixing members 4 are integrally formed, plural fixing members 4 can be easily disposed among a group of adjacent dye-sensitized solar cells 10, as compared with the case shown in FIG. 8B.

Furthermore, according to the present embodiment, when the fixing unit is an external linkage fixing unit having electrical conductivity, and the fixing members fixed by the external linkage fixing unit are electrically conductive, the fixing unit can be suitably used to connect between the electrode layers of adjacent dye-sensitized solar cells 10 by means of the fixing member 4 as shown in FIG. 3, FIG. 4 and FIG. 6.

There are no particular limitations on such a fixing unit, as long as it is capable of fixing the fixing member and preventing the fixing member from falling out from the dye-sensitized solar cell module. The fixing unit may be integrally formed with fixing members, or may be formed separately from fixing members. The fixing members used herein may be electrically conductive, or may be non-conductive.

There are no particular limitations on the shape of the fixing unit as long as the fixing unit can fix the fixing member at predefined positions in the dye-sensitized solar cell module, and the fixing unit can be appropriately selected and used in accordance with the shape of the fixing member.

Specific examples of such a fixing unit include a fixing unit formed by folding the fixing member into a predefined shape, and a fixing unit formed separately at an edge of the fixing member, using a conductive material or an insulating material.

2. Resin Substrate

Next, a pair of resin substrates that are used in the present embodiment will be described. Here, the resin substrates are substrates having flexibility.

The term flexibility means that the material is bendable when a force of 5 kN is applied by the bending test method for fine ceramics according to JIS R1601.

Here, the dye-sensitized solar cell used in the dye-sensitized solar cell module needs to receive sunlight through at least one of the oxide semiconductor electrode layer side or the counter electrode layer side. Therefore, it is necessary that at least one of the pair of resin substrates be a transparent resin substrate. Conventionally, transparent resin substrates are used for both of the resin substrates.

There are no particular limitations on the transparency of the transparent resin substrate as long as the transparent resin substrate is capable of transmitting sunlight so that the dye-sensitized solar cell module of the present embodiment can receive sunlight and thereby exhibit its functions, but according to the present embodiment, it is more preferable that the transparent resin substrate have a total light transmittance of 80% or greater. The total light transmittance is a value measured by a measurement method according to JIS K7361-1:1997.

Examples of the resin substrate that can be used include base materials formed from a polyethylene terephthalate film (PET), a polyester naphthalate film (PEN), and a polycarbonate film (PC).

The thickness of the resin substrate used in the present embodiment maybe appropriately selected in accordance with the use of the dye-sensitized solar cell module or the like. Usually, the thickness is preferably in the range of 10 μm to 2000 μm, particularly preferably in the range of 50 μm to 1800 μm, and more preferably in the range of 100 μm to 1500 μm.

3. Dye-Sensitized Solar Cell

Next, the dye-sensitized solar cell used in the present embodiment will be described. The dye-sensitized solar cell used in the present embodiment comprises an oxide semiconductor electrode layer which includes a first electrode layer formed on the surface of one of the resin substrates, and a porous layer formed on the first electrode layer and containing a dye-sensitizer-supported fine particle of a metal oxide semiconductor; a counter electrode layer which includes a second electrode layer formed on the surface of the other resin substrate, and a catalyst layer formed on the second electrode layer; and an electrolyte layer provided between the porous layer and the catalyst layer and containing a redox couple. The respective members will be described below.

(1) Oxide Semiconductor Electrode Layer

The oxide semiconductor electrode layer used in the present embodiment includes a first electrode layer formed on the surface of one of the resin substrates, and a porous layer formed on the first electrode layer and containing a dye-sensitizer-supported fine particle of a metal oxide semiconductor.

The first electrode layer and the porous layer will be respectively described below.

(a) First Electrode Layer

The first electrode layer used in the present embodiment will be explained. The first electrode layer used in the present embodiment is a layer formed on the surface of one of the resin substrates.

Furthermore, the first electrode layer may be an electrode layer having transparency, or may be an electrode layer which does not have transparency. As discussed above, since the dye-sensitized solar cell used in the present embodiment needs to receive sunlight through at least one of the oxide semiconductor electrode layer side or the counter electrode layer side, in the case of receiving sunlight through the oxide semiconductor electrode layer side, the first electrode layer needs to be an electrode layer having transparency. Furthermore, in this case, a transparent resin substrate is used as the resin substrate constituting the first electrode layer.

When the first electrode layer is an electrode layer having transparency, specific examples of the electrode layer include a transparent electrode layer, a mesh grid electrode layer, and an electrode layer having a transparent electrode layer and a mesh grid electrode layer. Furthermore, when the first electrode layer is an electrode layer which does not have transparency, the first electrode layer may be a metal layer.

The respective electrode layers will be described below.

(i) Transparent Electrode Layer

The material that constitutes the transparent electrode layer used in the present embodiment is not particularly limited as long as it is a material having transparency and predefined electrical conductivity, and a conductive polymer material, a metal oxide and the like can be used.

There are no particular limitations on the metal oxide as long as the substance has desired electrical conductivity. Among others, the metal oxide used in the present embodiment is preferably a metal oxide capable of transmitting sunlight. Examples of such a metal oxide capable of transmitting sunlight include SnO₂, ZnO, a compound obtained by adding tin to indium oxide (ITO), SnO₂ doped with fluorine (hereinafter, referred to as FTO), and a compound obtained by adding zinc oxide to indium oxide (IZO).

On the other hand, examples of the conductive polymer material include polythiophene, polyethylene sulfonic acid (PSS), polyaniline (PA), polypyrrole, and polyethylenedioxythiophene (PEDOT). These may also be used as mixtures of two or more kinds.

The transparent electrode layer used in the present embodiment may have a configuration composed of a single layer, or may have a configuration composed of a laminate of plural layers. Examples of the configuration composed of a laminate of plural layers include a configuration in which layers respectively formed from materials having different work functions are laminated, and a configuration in which layers formed from different metal oxides are laminated.

Typically, the thickness of the transparent electrode layer used in the present embodiment is preferably in the range of 5 nm to 2000 nm, and particularly preferably in the range of 10 nm to 1000 nm. If the thickness is greater than the range described above, it may become difficult to form a uniform transparent electrode layer, or the total light transmittance may be decreased so that it becomes difficult to obtain satisfactory photoelectric conversion efficiency. Furthermore, if the thickness is smaller than the range described above, there is a possibility that the electrical conductivity of the transparent electrode layer may be insufficient.

When the transparent electrode layer is composed of plural layers, the thickness as used herein refers to the total thickness as the sum of the thicknesses of all layers.

The method for forming the transparent electrode layer on a base material maybe similar to a general method for forming an electrode layer, and therefore, further description on the method will not be given here.

(ii) Mesh Grid Electrode Layer

Next, the mesh grid electrode layer will be described. The mesh grid electrode layer used in the present embodiment is an electrode layer formed in a mesh shape using an electrically conductive material.

The shape of mesh for the mesh grid electrode layer may be, for example, a triangular lattice shape, a parallelogram lattice shape, or a hexagonal lattice shape.

The thickness of the mesh grid electrode layer is preferably in the range of 0.01 μm to 10 μm. It is because if the thickness of the mesh grid electrode layer is greater than the range described above, more materials and longer time are needed to form the mesh grid electrode layer, and therefore, the production efficiency may be decreased, or the production cost may increase. Also, if the thickness of the mesh grid electrode layer is smaller than the range described above, there is a possibility that the mesh grid electrode layer may not sufficiently accomplish the function as an electrode layer.

The ratio of openings of the mesh grid electrode layer used in the present embodiment is preferably in the range of 50% to 99.9%. It is because, if the ratio of openings of the mesh grid electrode layer is lower than the range described above, the dye-sensitized solar cell of the present embodiment cannot sufficiently receive sunlight through the first electrode layer side, and therefore, there is a possibility that the power generation efficiency may be decreased. Furthermore, if the ratio of openings of the mesh grid electrode layer is greater than the range described above, there is a risk that it may be difficult to have the mesh grid electrode layer functionally improved as an electrode layer.

Furthermore, the wire width of the mesh grid electrode layer and the opening width of the mesh grid electrode layer may be appropriately selected in accordance with the shape of the dye-sensitized solar cell used. However, the wire width of the mesh grid electrode layer is preferably in the range of 0.02 μm to 10 mm, more preferably in the range of 1 μm to 2 mm, and particularly preferably in the range of 10 μm to 1 mm. The opening width of the mesh grid electrode layer is preferably in the range of 1 μm to 2000 μm, more preferably in the range of 10 μm to 1000 μm, and particularly preferably in the range of 100 μm to 500 μm.

There are no particular limitations on the material of the mesh grid electrode layer as long as it is a material having electrical conductivity, and specific examples include the same metals used in the metal layer that will be described in the section “(iv) Metal layer” given below.

(iii) Electrode Layer Having Transparent Electrode Layer and Mesh Grid Electrode Layer

An electrode layer which includes the above-mentioned transparent electrode layer and mesh grid electrode layer can be used as the first electrode layer used in the present embodiment. When the first electrode layer has a configuration such as described above, in the case where the conductivity of the transparent electrode layer is insufficient, the mesh grid electrode layer may supplement the conductivity. Therefore, it is advantageous in that the dye-sensitized solar cell of the present embodiment can have superior power generation efficiency.

The details of the transparent electrode layer and the mesh grid electrode layer are the same as described above, and thus, further description will not be repeated here.

(iv) Metal Layer

As discussed above, when the first electrode layer used in the present embodiment is an electrode layer which does not have transparency, a metal layer may be used. There are no particular limitations on the metal layer as long as it is a metal layer having flexibility, but examples of the material include copper, aluminum, titanium, chromium, tungsten, molybdenum, platinum, tantalum, niobium, zirconium, zinc, various stainless steels, and alloys thereof. Among them, titanium, chromium, tungsten, various stainless steels and alloys thereof are preferred. When a first electrode layer composed of a metal layer is used, the thickness of the metal layer is not particularly limited, as long as the thickness has flexibility and can impart self-supportability to the first electrode layer so that the porous layer can be formed on the first electrode layer. However, typically, the thickness of the metal layer is preferably in the range of 5 μm to 1000 μm, more preferably in the range of 10 μm to 500 μm, and even more preferably in the range of 20 μm to 200 μm.

(b) Porous Layer

The porous layer used in the present embodiment is a layer formed on the above-mentioned first electrode layer and containing a dye-sensitizer-supported fine particle of a metal oxide semiconductor on the surface.

(i) Fine Particle of Metal Oxide Semiconductor

There are no particular limitations on the fine particle of metal oxide semiconductor (may referred as metal oxide semiconductor fine particles) used in the present embodiment as long as the fine particles are formed of a metal oxide having semiconductor properties. Examples of the metal oxide constituting the metal oxide semiconductor fine particles used in the present embodiment include TiO₂, ZnO, SnO₂, ITO, ZrO₂, MgO, Al₂O₃, CeO₂, Bi₂O₃, Mn₃O₄, Y₂O₃, WO₃, Ta₂O₅, Nb₂O₅, and La₂O₃.

Among them, according to the present embodiment, metal oxide semiconductor fine particles formed of TiO₂ are most preferably used. This is because TiO₂ has particularly excellent semiconductor properties.

The average particle size of the metal oxide semiconductor fine particles used in the present embodiment is, typically, preferably in the range of 1 nm to 10 μm, and particularly preferably in the range of 10 nm to 1000 nm.

(ii) Dye Sensitizer

The dye sensitizer used in the present embodiment is not particularly limited as long as it is capable of generating an electromotive force by absorbing light. Such a dye sensitizer may be an organic dye, or a metal complex dye. Examples of the organic dye include acridine dyes, azo dyes, indigo dyes, quinone dyes, coumarin dyes, merocyanine dyes, phenylxanthene, indoline, and carbazole dyes. According to the present embodiment, among these organic dyes, coumarin dyes are used with preference. As the metal complex dye, it is preferable to use a ruthenium-based dye, and it is particularly preferable to use a ruthenium bipyridine dye and a ruthenium terpyridine dye, which are ruthenium complexes. It is because, since these ruthenium complexes have light absorption over broad wavelength ranges, the wavelength region of the light that can be photoelectrically converted may be broadened to a large extent.

(iii) Optional Components

The porous layer used in the present embodiment may contain optional components in addition to the metal oxide semiconductor fine particles. An example of the optional components used in the present embodiment may be a resin. It is because when the porous layer contains a resin, the brittleness problem of the porous layer used in the present embodiment can be improved. Examples of such a resin include polyvinylpyrrolidone, ethyl cellulose, and caprolactam.

(iv) Others

The thickness of the porous layer used in the present embodiment is, typically, preferably in the range of 1 μm to 100 μm, and particularly preferably in the range of 3 μm to 30 μm.

The method for forming the porous layer used in the present embodiment may be similar to the method for forming a porous layer used to form a general dye-sensitized solar cell, and therefore, further description on the method will not be given here.

(2) Counter Electrode Layer

The counter electrode layer used in the present embodiment is a layer which includes a second electrode layer formed on the surface of the other resin substrate, and a catalyst layer formed on the second electrode layer. The respective layers will be described below.

(a) Second Electrode Layer

The second electrode layer used in the present embodiment is not particularly limited as long as it can be used as a counter electrode layer of a dye-sensitized solar cell by forming thereon a catalyst layer that will be described below. The second electrode layer may be an electrode layer having transparency, or may be an electrode layer which does not have transparency. As described above, the dye-sensitized solar cell used in the present embodiment needs to receive sunlight through at least one of the oxide semiconductor electrode layer side and the counter electrode layer side. Therefore, when the dye-sensitized solar cell receives sunlight through the counter electrode layer side, an electrode layer having transparency is used as the second electrode layer. Furthermore, in this case, a transparent resin substrate is used for the resin substrate on which the second electrode layer is formed.

In regard to the second electrode layer, the same electrode layer as that described in the section for the first electrode layer can be used, and therefore, further description will not be repeated here.

(b) Catalyst Layer

The catalyst layer used in the present embodiment is formed on the second electrode layer. When the catalyst layer is formed on the second electrode layer, the dye-sensitized solar cell used in the present embodiment can have superior power generation efficiency. Examples of such a catalyst layer include a catalyst layer obtained by depositing platinum (Pt) on the second electrode layer, and a catalyst layer formed from polyethylenedioxythiophene (PEDOT), polystyrene sulfonic acid (PSS), polyaniline (PA), para-toluenesulfonic acid (PTS) or mixtures thereof, but there are no limitations in the constitution.

The thickness of such a catalyst layer is preferably in the range of 1 nm to 10 μm, more preferably in the range of 10 nm to 1000 nm, and particularly preferably in the range of 10 nm to 500 nm.

(3) Electrolyte Layer

Next, the electrolyte layer used in the present embodiment will be described.

The electrolyte layer used in the present embodiment is formed between the porous layer and the catalyst layer, and contains a redox couple.

The redox couple used in the electrolyte layer according to the present embodiment is not particularly limited as long as it is a redox couple generally used in the electrolyte layer of dye-sensitized solar cells. Among others, the redox couple used in the present embodiment is preferably a combination of iodine and an iodide, or a combination of bromine and a bromide.

The combination of iodine and an iodide used in the present embodiment as the redox couple may be, for example, a combination of a metal iodide such as LiI, NaI, KI or CaI₂, with I₂.

The combination of bromine and a bromide may be, for example, a combination of a metal bromide such as LiBr, NaBr, KBr, or CaBr₂, with Br₂.

The electrolyte layer according to the present embodiment may also contain, as additional compounds other than the redox couple, additives such as a crosslinking agent, a photopolymerization initiator, a thickening agent, and a room temperature molten salt.

The electrolyte layer used in the present embodiment may be an electrolyte layer that is in any one of a gel form, a solid form and a liquid form, but an electrolyte layer in a solid form is more preferred. The electrolyte layer in a solid form does not easily cause problems such as liquid leakage, and is easy to handle.

(4) Additional Constitution

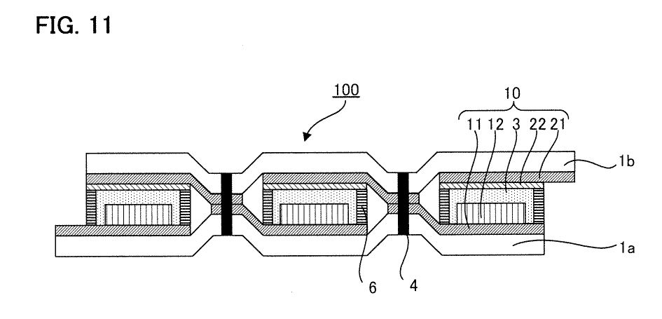

The dye-sensitized solar cell used in the present embodiment is not particularly limited as long as the solar cell has the oxide semiconductor electrode layer, the counter electrode layer and the electrolyte layer, and any necessary members may be appropriately added to the solar cell and used. An example of such a member may be, as shown in FIG. 11, a sealing material 6 for sealing in the case of using an electrolyte layer 3 in a liquid form or a gel form as the electrolyte layer of the present embodiment. Such a sealing material 6 may be similar to the sealing materials used in general dye-sensitized solar cells, and therefore, further explanations will not be given here. FIG. 11 is a schematic cross-sectional diagram showing another example of the dye-sensitized solar cell module of the present embodiment, and the reference numerals that are not described herein have the same meanings as the reference numerals described in conjunction with FIG. 1. Thus, further description will not be repeated here.

4. Other Members

There are no particular limitations on the dye-sensitized solar cell module of the present embodiment as long as the dye-sensitized solar cell module includes the above-mentioned fixing member, resin substrates, and dye-sensitized solar cells, and configurations other than those described above can be appropriately selected and used. As such a configuration, a sealing unit for sealing the penetrating hole formed at the position where the fixing member is penetrated through from the external side of a resin substrate, may be mentioned. According to the present embodiment, when the sealing unit is provided, moisture in the atmosphere can be prevented from infiltrating into the dye-sensitized solar cell module. Here, if moisture has infiltrated into the dye-sensitized solar cell module, there can be contemplated a possibility that the dye sensitizer supported on the porous layer may be eliminated, and thereby the dye-sensitized solar cell may be deteriorated over time. Therefore, it is preferable to form a sealing unit.

Since the sealing unit can be formed by using a general resin material, further description will not be given here.

Furthermore, in regard to the dye-sensitized solar cell module of the present embodiment, it is preferable that an electrically conductive material be disposed between the electrode layers of adjacent dye-sensitized solar cells. Thereby, connection between the electrode layers can be achieved more suitably.

The electrically conductive material used in the present embodiment may be the same material used in general dye-sensitized solar cell modules, and examples include a metal paste, and a conductive polymer compound.

### II. Dye-Sensitized Solar Cell Module of Embodiment 2

Next, Embodiment 2 of the dye-sensitized solar cell module of the present invention will be described.

The dye-sensitized solar cell module of the present embodiment is a dye-sensitized solar cell module comprising two or more dye-sensitized solar cells formed therein, each dye-sensitized solar cell having: a metal layer having flexibility; a transparent resin substrate having flexibility, and carrying an electrode layer having transparency formed on one surface of the transparent resin substrate; a porous layer formed in a pattern on a surface of the metal layer or a surface of the electrode layer having transparency, and containing a dye-sensitizer-supported fine particle of a metal oxide semiconductor; a catalyst layer formed on the surface of the metal layer or the surface of the electrode layer having transparency, where the porous layer is not formed; and an electrolyte layer provided between the porous layer and the catalyst layer and containing a redox couple, wherein a fixing member having insulating properties is disposed between adjacent dye-sensitized solar cells and the fixing member penetrates through from an external side of the metal layer to an external side of the transparent resin substrate.

The dye-sensitized solar cell module of the present embodiment has plural dye-sensitized solar cells formed on the same metal layer, and the respective dye-sensitized solar cells are connected in parallel.

According to the present embodiment, as the fixing member is formed so as to penetrate through from the external side of the metal layer to the external side of the transparent resin substrate, even in the case where the dye-sensitized solar cell module is bent many times due to the use for a long time period, the metal layer and the transparent resin substrate can be maintained in a predefined positional relationship. Thereby, a dye-sensitized solar cell module having excellent durability can be obtained. Furthermore, when the metal layer and the transparent resin substrate are fixed by the fixing member, internal short circuit can be prevented.

The dye-sensitized solar cell module of the present embodiment can be divided into two embodiments such as an embodiment in which a porous layer is formed on the metal layer (hereinafter, referred to as embodiment A), and an embodiment in which a catalyst layer is formed on the metal layer (hereinafter, referred to as embodiment B). The respective embodiments will be described below.

1. Dye-Sensitized Solar Cell Module of Embodiment A

The dye-sensitized solar cell module of the present embodiment is a dye-sensitized solar cell module comprising two or more dye-sensitized solar cells, each dye-sensitized solar cell having a metal layer having flexibility; a transparent resin substrate having flexibility, and carrying an electrode layer having transparency formed on one surface of the transparent resin substrate; a porous layer formed in a pattern on the surface of the metal layer and containing a dye-sensitizer-supported fine particle of a metal oxide semiconductor; a catalyst layer formed on the surface of the electrode layer having transparency; and an electrolyte layer provided between the porous layer and the catalyst layer and containing a redox couple, wherein a fixing member having insulating properties is disposed between adjacent dye-sensitized solar cells and the fixing member is formed so as to penetrate through from the external side of the metal layer to the external side of the transparent resin substrate.

Here, the dye-sensitized solar cell module of the present embodiment will be described with reference to the attached drawings.

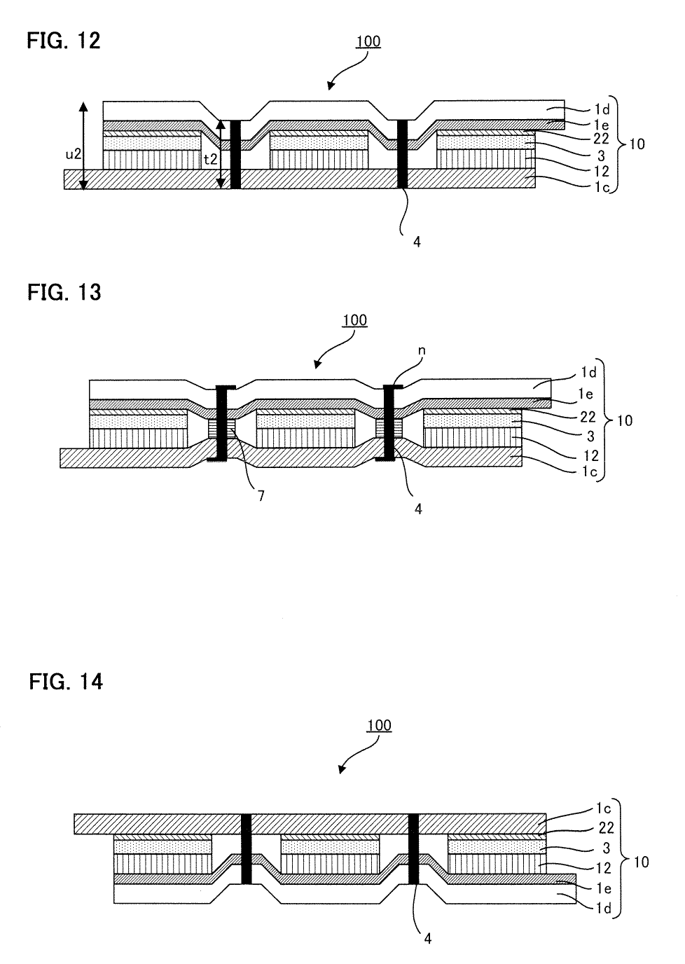

FIG. 12 is a schematic cross-sectional diagram showing an example of the dye-sensitized solar cell module of the present embodiment. As shown in FIG. 12, the dye-sensitized solar cell module 100 of the present embodiment comprises two or more dye-sensitized solar cells 10 (in FIG. 12, three dye-sensitized solar cells 10) formed therein, each dye-sensitized solar cell 10 has a metal layer 1c having flexibility; a transparent resin substrate 1d having flexibility, and carrying an electrode layer 1e having transparency formed on one surface of the substrate; a porous layer 12 formed in a pattern on the surface of the metal layer 1c and containing a dye-sensitizer-supported fine particle of a metal oxide semiconductor; a catalyst layer 22 formed on the surface of the electrode layer 1e having transparency; and an electrolyte layer 3 provided between the porous layer 12 and the catalyst layer 22 and containing a redox couple, and a fixing member 4 having insulating properties is disposed between adjacent dye-sensitized solar cells 10 and the fixing member 4 is formed to penetrate through from the external side of the metal layer 1c to the external side of the transparent resin substrate 1d. FIG. 12 presents an example in which a solid electrolyte layer is used as the electrolyte layer 3.

There are no particular limitations on the position at which the fixing member is disposed, as long as the fixing member can be formed at that position so as to penetrate through from the external side of the metal layer to the external side of the transparent resin substrate, and the fixing member can be disposed between adjacent dye-sensitized solar cells in a manner such that the metal layer and the electrode layer having transparency are not connected. However, a position at which the fixing member is not brought into contact with the porous layer and the electrolyte layer of the dye-sensitized solar cell, is preferred. This is because the fixing member can be easily disposed thereby.

In regard to the placement of the fixing member, there are no particular limitations on the placement as long as the fixing member can be formed so as to penetrate through from the external side of the metal layer to the external side of the transparent resin substrate, and can be disposed between adjacent dye-sensitized solar cells in a manner such that the metal layer and the electrode layer having transparency are not connected. Among others, it is preferable that the fixing member is disposed in the dye-sensitized solar cell module of the present embodiment such that the thickness of the portion fixed by the fixing member is smaller than the thickness of the portion where the dye-sensitized solar cell is formed.

Here, the “thickness of the portion fixed by the fixing member” according to the present embodiment refers to a distance t2 from the external surface of the metal layer 1c to the external surface of the transparent resin substrate 1d of the portion where the fixing member 4 is disposed, as shown in FIG. 12. The “thickness of the portion where the dye-sensitized solar cell is formed” refers to a distance u2 from the external surface of the metal layer 1c to the external surface of the transparent resin substrate 1d at the portion where the dye-sensitized solar cell 10 is formed, as shown in FIG. 12.

The respective members used in the present embodiment will be described below.

(1) Fixing Member

The fixing member used in the present embodiment is disposed between the adjacent dye-sensitized solar cells, and is formed so as to penetrate through from the external side of the metal layer to the external side of the transparent resin substrate. Furthermore, the fixing member according to the present embodiment fixes the metal layer and the transparent resin substrate in a manner such that the metal layer and the electrode layer having transparency are not connected.

There are no particular limitations on the material of the fixing member used in the present embodiment as long as the material has insulating properties and can form a fixing member that penetrates through from the external side of the metal layer to the external side of the transparent resin substrate. Specifically, the same materials as the materials for the fixing member that is non-conductive as described in the section of “I. Dye-sensitized solar cell module of Embodiment 1” can be used, and thus further description will not be repeated here.

Furthermore, there are also no particular limitations on the shape, number, position of formation and the like of the fixing member, as long as the fixing member is formed so as to penetrate through from the external side of the metal layer to the external side of the transparent resin substrate, and can fix the metal layer and the transparent resin substrate in a manner such that the metal layer and the electrode layer having transparency are not connected. Specifically, the fixing member having the same characteristic to the fixing member as described in the section of “I. Dye-sensitized solar cell module of Embodiment 1” can be used, and thus further description will not be repeated here.

(2) Metal Layer

The metal layer used in the present embodiment is a layer having flexibility.

The flexibility of the metal layer used in the present embodiment means that the metal layer is bendable when a force of 5 kN is applied by the bending test method for metallic materials according to JIS Z 2248.

In regard to the metal layer used in the present embodiment, the same metal layer as that used in the first electrode layer described in the section of “I. Dye-sensitized solar cell module of Embodiment 1” can be used, and therefore, further description will not be repeated here.

(3) Transparent Resin Substrate

The transparent resin substrate used in the present embodiment is a substrate having flexibility. In regard to the transparent resin substrate, the same transparent resin substrate as that used for the resin substrate described in the section of “I. Dye-sensitized solar cell module of Embodiment 1” can be used, and therefore, further description will not be repeated here.

(4) Porous Layer

The porous layer used in the present embodiment is a layer formed in a pattern on the surface of the metal layer. In regard to such a porous layer, the same porous layer as that described in the section of “I. Dye-sensitized solar cell module of Embodiment 1” can be used, and therefore, further description will not be repeated here.

(5) Electrode Layer Having Transparency and Catalyst Layer

The electrode layer having transparency used in the present embodiment is formed on the surface of the transparent resin substrate. In regard to the electrode layer having transparency, the same electrode layer having transparency as that used in the first electrode layer described in the section of “I. Dye-sensitized solar cell module of Embodiment 1” can be used, and therefore, further description will not be repeated here.

Since the dye-sensitized solar cell module of the present embodiment has two or more dye-sensitized solar cells connected in parallel, the electrode layer having transparency is usually formed over the entire surface of the transparent resin substrate.

However, since there is a possibility that the region where the fixing member is provided may short circuit with the metal layer, the electrode layer having transparency may be an electrode layer having transparency, from which the aforementioned region has been partially removed.

There are no particular limitations on the catalyst layer used in the present embodiment as long as it is formed on the electrode layer having transparency, and the catalyst layer may be formed over the entire surface of the electrode layer having transparency, or may be formed in a pattern on the electrode layer having transparency in accordance with the shape of the porous layer. However, it is more preferable that the catalyst layer be formed in a pattern. This is because the production cost for the dye-sensitized solar cell module of the present embodiment can be reduced.

In regard to the details of the catalyst layer used in the present embodiment, the same catalyst layer as that described in the section of “I. Dye-sensitized solar cell module of Embodiment 1” can be used, and therefore, further description will not be repeated here.

(6) Additional Constitution

The dye-sensitized solar cell module of the present embodiment is not particularly limited as long as the solar cell module has the fixing member, the metal layer, the transparent resin substrate, and the dye-sensitized solar cell, and in addition to these, any necessary constitution can be appropriately selected and used.

An example of this constitution may be a sealing unit for sealing the penetration hole formed at the position where the fixing member is penetrated through from the external side of the resin substrate. In regard to the sealing unit, the same sealing unit described in the section of “I. Dye-sensitized solar cell module of Embodiment 1” can be used, and therefore, further description will not be repeated here.

According to the present embodiment, since there is a need to dispose the fixing member in a manner not to bring the metal layer and the electrode layer having transparency into contact, it is preferable that, as shown in FIG. 13, an insulating layer 7 be formed between the metal layer 1c and the electrode layer 1e having transparency in the region where the fixing member 4 is formed. Thereby, the contact between the metal layer 1c and the electrode layer 1e having transparency can be securely prevented, and therefore, a dye-sensitized solar cell module 100 which is free from internal short circuit may be obtained. FIG. 13 presents an example in which the fixing unit 4 has a fixing unit n.

The insulating layer is not particularly limited as long as it has insulating properties, and the insulating layer can be formed by using the insulating material that is used in general dye-sensitized solar cell modules.

According to the present embodiment, when the catalyst layer is formed in a pattern on the electrode layer having transparency, it is preferable to provide wiring in the region on the electrode layer having transparency, where the catalyst layer is not formed. Since the electrode layer having transparency is usually formed over the entire surface of the transparent resin substrate, when the dye-sensitized solar cell is made large in size, there is a risk that the resistance may increase, and the electrical conductivity may be decreased. Thus, it is preferable to provide the wiring, and thereby to prevent a decrease in the electrical conductivity of the electrode layer having transparency.

In regard to the wiring, the same wiring as that used in general dye-sensitized solar cell module can be used, and therefore, further description will not be repeated here.

2. Dye-Sensitized Solar Cell Module of Embodiment B

The dye-sensitized solar cell module of the present embodiment is a dye-sensitized solar cell module comprising two or more dye-sensitized solar cells, each dye-sensitized solar cell has a metal layer having flexibility; a transparent resin substrate having flexibility, and carrying an electrode layer having transparency formed on one surface of the substrate; a porous layer formed in a pattern on the surface of the electrode layer having transparency and containing a dye-sensitizer-supported fine particle of a metal oxide semiconductor; a catalyst layer formed on the surface of the metal layer; and an electrolyte layer provided between the porous layer and the catalyst layer and containing a redox couple, wherein a fixing member having insulating properties is disposed between adjacent dye-sensitized solar cells and the fixing member is formed so as to penetrate through from the external side of the metal layer to the external side of the transparent resin substrate.

Here, the dye-sensitized solar cell module of the present embodiment will be described with reference to the attached drawings. FIG. 14 is a schematic cross-sectional diagram showing an example of the dye-sensitized solar cell module of the present embodiment. As shown in FIG. 14, the dye-sensitized solar cell module 100 of the present embodiment comprises two or more dye-sensitized solar cells 10 (in FIG. 14, three dye-sensitized solar cells 10) formed therein, each dye-sensitized solar cell 10 having a metal layer 1c having flexibility; a transparent resin substrate 1d having flexibility, and carrying an electrode layer 1e having transparency formed on one surface of the substrate; a porous layer 12 formed on the surface of the electrode layer 1e having transparency and containing a dye-sensitizer-supported fine particle of a metal oxide semiconductor; a catalyst layer 22 formed on the surface of the metal layer 1c; and an electrolyte layer 3 provided between the porous layer 12 and the catalyst layer 22 and containing a redox couple, and a fixing member 4 having insulating properties is disposed between adjacent dye-sensitized solar cells 10 such that the fixing member 4 is formed to penetrate through from the external side of the metal layer 1c to the external side of the transparent resin substrate 1d.

FIG. 14 presents an example in which a solid electrolyte layer is used as the electrolyte layer 3.

The difference between the dye-sensitized solar cell module of the present embodiment and the dye-sensitized solar cell module of the embodiment A is a configurational difference between the dye-sensitized solar cells, which is based on the difference in the placement of the metal layer and the transparent resin substrate. In regard to the placement of the fixing member according to the present embodiment, or in regard to the fixing member, the metal layer, the transparent resin substrate, the electrode layer having transparency and other configurations as used in the present embodiment, the same items as those described in the section of “1. Dye-sensitized solar cell module of embodiment A” can be used, and therefore, further description will not be repeated here.

The porous layer used in the present embodiment is a layer formed in a pattern on the electrode layer having transparency of the transparent resin substrate. In regard to the porous layer, the same porous layer as that used in the section of “1. Dye-sensitized solar cell module of embodiment A”, except for being formed on the electrode layer having transparency, can be used, and therefore, further description will not be repeated here.

Furthermore, the catalyst layer used in the present embodiment is formed on the metal layer. In regard to the catalyst layer, the same catalyst layer as that described in the section of “1. Dye-sensitized solar cell module of embodiment A”, except for being formed on the metal layer, can be used, and therefore, further description will not be repeated here.

B. Method for Producing Dye-Sensitized Solar Cell Module

Next, the method for producing the dye-sensitized solar cell module of the present invention will be described.

The method for producing the dye-sensitized solar cell module of the present invention can be divided into two embodiments such as a method for producing the dye-sensitized solar cell module of Embodiment 1 (hereinafter, referred to as Embodiment 3), and a method for producing the dye-sensitized solar cell module of Embodiment 2 (hereinafter, referred to as embodiment 4) as described in the above-mentioned section of “A. Dye-sensitized solar cell module”. The respective embodiments will be described below.

### I. Method for Producing Dye-Sensitized Solar Cell Module of Embodiment 3

The method for producing a dye-sensitized solar cell module of the present embodiment is a method for producing a dye-sensitized solar cell module comprising a pair of resin substrates having flexibility, and at least two dye-sensitized solar cells formed between the pair of resin substrates, the method comprises steps of: forming at least two dye-sensitized solar cells, each having an oxide semiconductor electrode layer which includes a first electrode layer formed on the surface of one of the resin substrates, and a porous layer formed on the first electrode layer and containing a dye-sensitizer-supported fine particle of a metal oxide semiconductor; a counter electrode layer which includes a second electrode layer formed on the surface of the other resin substrate, and a catalyst layer formed on the second electrode layer; and an electrolyte layer provided between the porous layer and the catalyst layer and containing a redox couple; and disposing a fixing member between adjacent dye-sensitized solar cells, by forming the fixing member so as to penetrate through from the external side of one of the resin substrates to the external side of the other resin substrate.

Here, the method for producing a dye-sensitized solar cell module of the present embodiment will be described with reference to the attached drawings.

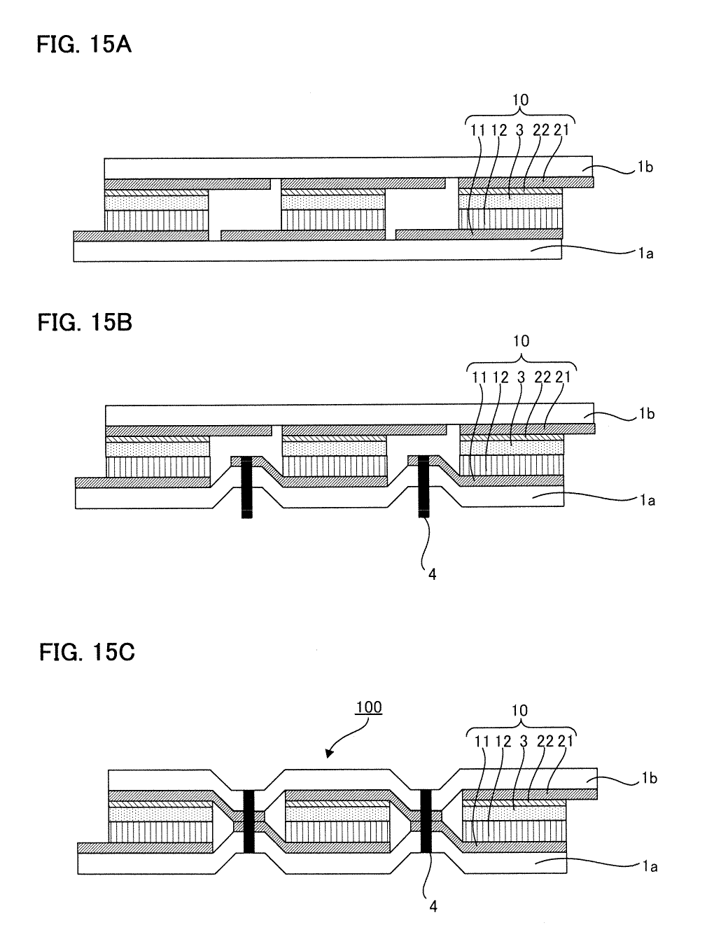

FIGS. 15A to 15C are a process diagram showing an example of the method for producing a dye-sensitized solar cell module of the present embodiment. As shown in FIGS. 15A to 15C, the method for producing a dye-sensitized solar cell module of the present embodiment is a method for producing a dye-sensitized solar cell module having a pair of a resin substrate 1a and a resin substrate 1b, both having flexibility, and two or more dye-sensitized solar cells 10 formed between the resin substrates, and is a method comprising steps of: a dye-sensitized solar cell forming step (FIG. 15A) of forming at least two dye-sensitized solar cells 10 (in FIGS. 15A to 15C, three dye-sensitized solar cells 10), each having an oxide semiconductor electrode layer which includes a first electrode layer 11 formed on the surface of the resin substrate 1a, and a porous layer 12 formed on the first electrode layer 11 and containing a dye-sensitizer-supported fine particle of a metal oxide semiconductor; a counter electrode layer which includes a second electrode layer 21 formed on the surface of the resin substrate 1b, and a catalyst layer 22 formed on the second electrode layer 21; and an electrolyte layer 3 provided between the porous layer 12 and the catalyst layer 22 and containing a redox couple; and a fixing member disposing step of disposing a fixing member 4 between the first electrode layer 11 and the second electrode layer 12 of adjacent dye-sensitized solar cells 10, by forming the fixing member 4 so as to penetrate through from the external side of the resin substrate 1a to the external side of the resin substrate 1b. In addition, FIG. 15B presents a process of forming the fixing member 4 to penetrate through the resin substrate 1a from the external side of the resin substrate 1a during fixing member disposing step, and FIG. 15C presents a process of fixing the positions of the resin substrate 1a and the resin substrate 1b by making the fixing member 4 that has penetrated through the resin substrate 1a, to penetrate through the first electrode layer 11 of one dye-sensitized solar cell 10 and the second electrode layer 12 of the other dye-sensitized solar cell 10 and to further penetrate to the external side of the resin substrate 1b, so that the first electrode layer 11 and the second electrode layer 21 are brought into contact.

According to the present embodiment, when the method includes the fixing member disposing step, a pair of resin substrates can be fixed such that the electrode layers are in a predefined positional relationship, by forming two or more dye-sensitized solar cells between the pair of resin substrates and then providing the fixing member. Therefore, a dye-sensitized solar cell module which has less connection failure and has excellent durability can be easily produced.

Respective steps used in the method for producing a dye-sensitized solar cell module of the present embodiment will be described below.

1. Dye-Sensitized Solar Cell Forming Step

Dye-sensitized solar cell forming step according to the present embodiment is a step of forming at least two dye-sensitized solar cells, each having an oxide semiconductor electrode layer which includes a first electrode layer formed on the surface of one of the resin substrates, and a porous layer formed on the first electrode layer and containing a dye-sensitizer-supported fine particle of a metal oxide semiconductor; a counter electrode layer which includes a second electrode layer formed on the surface of the other resin substrate, and a catalyst layer formed on the second electrode layer; and an electrolyte layer provided between the porous layer and the catalyst layer and containing a redox couple.

In regard to the method for forming a dye-sensitized solar cell used in present step, the same method as used to form a general dye-sensitized solar cell can be used. An example of the method for forming a dye-sensitized solar cell may be a method such as described below.

First, a pair of resin substrates is provided, and two or more first electrode layers are formed on the surface of one of the resin substrates. Subsequently, a porous layer is formed on each of the first electrode layers, and thereby oxide semiconductor electrode layers are formed. Furthermore, second electrode layers are formed in a number equal to the number of the oxide semiconductor electrode layers, on the surface of the other resin substrate, and then a catalyst layer is formed on each of the second electrode layers. Thus, counter electrode layers are formed. Subsequently, the pair of resin substrates is disposed such that the respective porous layers and the respective catalyst layers face each other, and the pair of resin substrates are sealed using a sealing material. Subsequently, an electrolyte in a liquid form or a gel form is injected in between the oxide semiconductor electrode substrate and the counter electrode substrate, and thereby an electrolyte layer is formed. Thus, a dye-sensitized solar cell is formed.

Furthermore, a method such as described below can also be used as the method for forming a dye-sensitized solar cell.

First, plural oxide semiconductor electrode layers are formed on one of the resin substrates, and plural counter electrode layers are formed on the other resin substrate, in the same manner as in the method for forming a dye-sensitized solar cell described above. Subsequently, solid electrolyte layers are formed on the porous layer of the oxide semiconductor electrode layers by applying the material for electrolyte layer in a solid form and drying the material, and then the pairing resin substrates are disposed such that the solid electrolyte layers and the catalyst layers are brought into contact to face each other. Thus, a dye-sensitized solar cell is formed.

In the present step, when a solid electrolyte layer is used as the electrolyte layer for the dye-sensitized solar cell thus formed, two or more dye-sensitized solar cells may be formed between a pair of resin substrates by using a Roll-to-Roll method.

The methods for forming a dye-sensitized solar cell described above are all examples, and according to the present embodiment, other general methods for forming a dye-sensitized solar cell may also be used.

In regard to the resin substrate and the respective members of the dye-sensitized solar cell used in the present step, the same substrates and members described in the section of “A. Dye-sensitized solar cell module” can be used, and therefore, further description will not be repeated here.

Also, the dye-sensitized solar cell formed in present step has been described in the section of “A. Dye-sensitized solar cell module”, and therefore, further description will not be repeated here.

2. Fixing Member Disposing Step

Present step is a step of disposing a fixing member between adjacent dye-sensitized solar cells described above, by forming the fixing member so as to penetrate through from the external side of one of the resin substrates to the external side of the other resin substrate.

In the present step, in regard to the placement of the fixing member, and the fixing member used in the present step, the same placement and fixing member as those described in the section of “A. Dye-sensitized solar cell module” can be used, and therefore, further description will not be repeated here.

There are no particular limitations on the method of disposing the fixing member as long as it is a method capable of disposing a fixing member between adjacent dye-sensitized solar cells by forming the fixing member to penetrate through from the external side of one of the resin substrates to the external side of the other resin substrate. For example, the method may be a method of providing in advance a penetration hole for disposing the fixing member, from the external sides of the pair of resin substrates, and inserting the fixing member through the penetration hole, or may be a method of directly making the fixing member to penetrate through from the external side of one of the resin substrates to the external side of the other resin substrate. However, a method of providing the fixing member by directly making the fixing member to penetrate through from the external side of one of the resin substrates to the external side of the other resin substrate, is more preferable. It is because fewer steps of forming the fixing member are required, and thus the production efficiency can be enhanced.

Specific examples of the method for providing the fixing member by directly making the fixing member to penetrate through from the external side of one of the resin substrates to the external side of the other resin substrate, include a method of using a needle-shaped fixing member and making the needle-shaped fixing member to penetrate through from the external side of one of the resin substrates to the external side of the other resin substrate; and a method of using a stapler and making the fixing member to penetrate through from the external side of one of the resin substrates to the external side of the other resin substrate.

3. Additional Steps

The method for producing a dye-sensitized solar cell module of the present embodiment is not particularly limited as long as it is a method including the above-mentioned dye-sensitized solar cell forming step and fixing member disposing step, and any necessary steps can be appropriately added. An example of such a step may be sealing unit forming step of forming a sealing unit which seals the penetration area of the fixing member using a resin material or the like. Another example of such a step may be conductive material disposing step of disposing a conductive material between the electrode layers of adjacent dye-sensitized solar cells. Furthermore, it is usually preferable that the conductive material disposing step be carried out simultaneously with the dye-sensitized solar cell forming step.

### II. Method for Producing Dye-Sensitized Solar Cell Module of Embodiment 4

The method for producing a dye-sensitized solar cell module of the present embodiment is a production method comprising steps of: forming two or more dye-sensitized solar cells, each having a metal layer having flexibility; a transparent resin substrate having flexibility, and carrying an electrode layer having transparency formed on one surface of the transparent resin substrate; a porous layer formed in a pattern on a surface of the metal layer or a surface of the electrode layer having transparency, and containing a dye-sensitizer-supported fine particle of a metal oxide semiconductor; a catalyst layer formed on the surface of the metal layer or the surface of the electrode layer having transparency, where the porous layer is not formed; and an electrolyte layer provided between the porous layer and the catalyst layer and containing a redox couple; and disposing a fixing member having insulating properties between adjacent dye-sensitized solar cells by forming the fixing member to penetrate through from the external side of the metal layer to the external side of the transparent resin substrate.

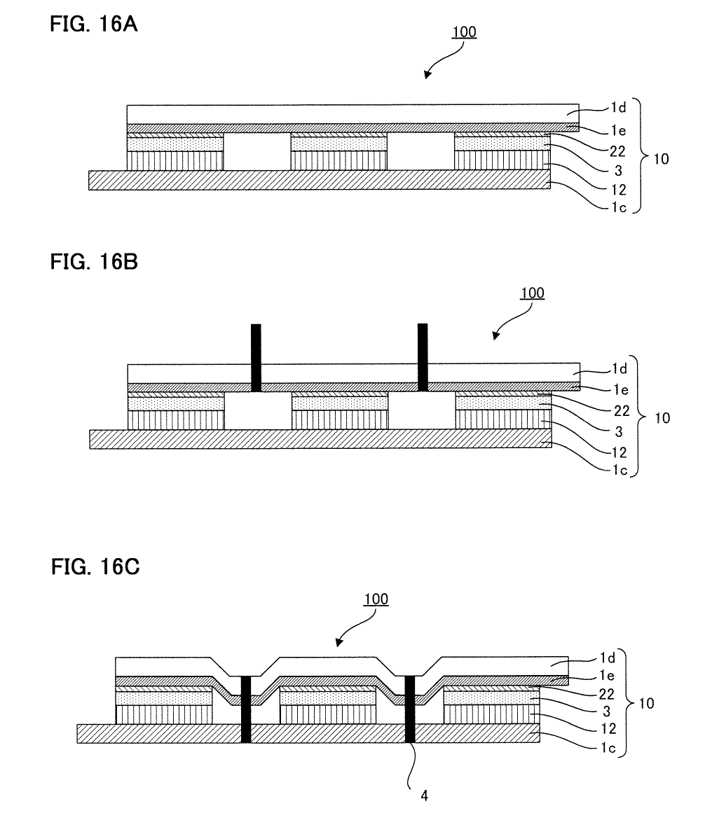

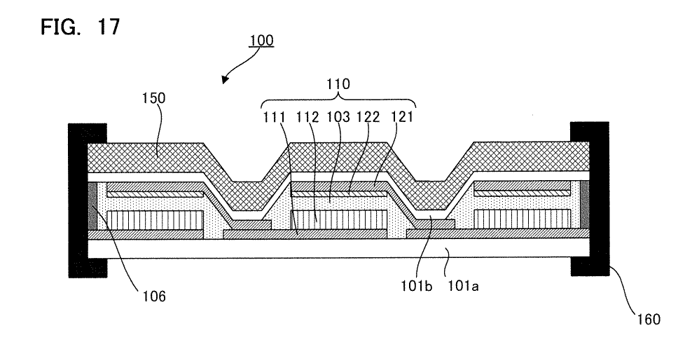

Here, the method for producing a dye-sensitized solar cell module of the present embodiment will be described with reference to the attached drawings. FIGS. 16A to 16C are a process diagram showing the method for producing a dye-sensitized solar cell module of the present embodiment. As shown in FIGS. 16A to 16C, the method for producing a dye-sensitized solar cell module of the present embodiment includes a dye-sensitized solar cell forming step (FIG. 16A) of forming two or more dye-sensitized solar cells 10 (in FIGS. 16A to 16C, three dye-sensitized solar cells 10), each having a metal layer 1c having flexibility; a transparent resin substrate 1d having flexibility, and carrying an electrode layer 1e having transparency which is formed on one surface of the substrate; a porous layer 12 formed in a pattern on the surface of the metal layer 1c and containing a dye-sensitizer-supported fine particle of a metal oxide semiconductor; a catalyst layer 22 formed on the surface of the electrode layer 1e having transparency of the transparent resin substrate 1d; and an electrolyte layer 3 provided between the porous layer 12 and the catalyst layer 22 and containing a redox couple; and a fixing member disposing step of disposing a fixing member 4 having insulating properties between adjacent dye-sensitized solar cells 10, by forming the fixing member 4 so as to penetrate through from the external side of the metal layer 1c to the external side of the transparent resin substrate 1d. FIG. 16B presents a process of forming the fixing member 4 to penetrate from the external side of the transparent resin substrate 1d to the interior during the fixing member disposing step, and FIG. 16C presents a process of disposing the fixing member 4 to penetrate from the external side of the transparent resin substrate 1d to the external side of the metal layer 1c.

Respective steps of the method for producing a dyes-sensitized solar cell module of the present embodiment will be described below.

1. Dye-Sensitized Solar Cell Forming Step

The dye-sensitized solar cell forming step according to the present embodiment is a step of forming two or more dye-sensitized solar cells, each having a metal layer having flexibility; a transparent resin substrate having flexibility, and carrying an electrode layer having transparency formed on one surface of the substrate; a porous layer formed in a pattern on a the surface of the metal layer or a surface of the electrode layer having transparency, and containing a dye-sensitizer-supported fine particle of a metal oxide semiconductor; a catalyst layer formed on any one of the surface of the metal layer and the surface of the electrode layer having transparency, where the porous layer is not formed; and an electrolyte layer provided between the porous layer and the catalyst layer and containing a redox couple.

In the dye-sensitized solar cell forming step according to the present embodiment, the same process as that used in dye-sensitized solar cell forming step described in the section of “1. Method for producing dye-sensitized solar cell module of Embodiment 3”, except for using the porous layer or the catalyst layer on the metal layer, can be used, and therefore, further description will not be repeated here.

In regard to the metal layer, transparent resin substrate, electrode layer having transparency, porous layer and catalyst layer used in the present step, the same members described in the section of “II. Dye-sensitized solar cell module of Embodiment 2” of “A. Dye-sensitized solar cell module” described above can be used, and therefore, further description will not be repeated here.

2. Fixing Member Disposing Step

The present step is a step of disposing a fixing member having insulating properties between adjacent dye-sensitized solar cells by forming the fixing member to penetrate through from the external side of the metal layer to the external side of the transparent resin substrate.

In regard to the fixing member used in the present step, the same fixing member as that described in the section of “II. Dye-sensitized solar cell module of Embodiment 2” can be used, and therefore, further description will not be repeated here.

Furthermore, in regard to the method of disposing the fixing member used in the present step, the same method as that described in the section of “1. Method for producing dye-sensitized solar cell module of Embodiment 3” can be used, and therefore, further description will not be repeated here.

3. Additional Steps

The method for producing a dye-sensitized solar cell module of the present embodiment is not particularly limited as long as it is a method including the above-mentioned dye-sensitized solar cell forming step and fixing member disposing step, and any necessary steps can be appropriately added. An example of such a step may be a sealing unit forming step. In regard to the sealing unit forming step, the same process as that described in the section of “1. Method for producing dye-sensitized solar cell module of Embodiment 3” can be used, and therefore, further description will not be repeated here. Another example of such a step may be an insulating layer forming step of forming an insulating layer between the electrode layers of the adjacent dye-sensitized solar cells. It is usually preferable that the insulating layer forming step be carried out simultaneously with the dye-sensitized solar cell forming step.

The present invention is not intended to be limited to the embodiments described above. The embodiments described above are only for illustrative purposes, and any embodiment which has substantially the same constitution as the technical idea described in the claims of the present invention and offers similar operating effects, is definitely included in the technical scope of the present invention.

### EXAMPLES

Hereinafter, the present invention will be described more specifically by way of Examples.

### Example 1

(Production of Oxide Semiconductor Electrode Layer)

On a titanium (Ti) foil substrate (manufactured by Etakeuchi Co., Ltd.) (first electrode layer) having a size of 50 mm×50 mm and a thickness of 50 μm, a paste prepared by mixing titanium oxide particles P25™ (manufactured by Nippon Aerosil Co. Ltd.) with 0.5% ethyl cellulose STD-100™ (manufactured by Nisshin Kasei Kogyo Co., Ltd.) in ethanol was applied and dried, and the paste was burned for 30 minutes at 500° C. Thus, a layer for porous layer formation was formed (thickness 5 μm). Subsequently, a liquid was prepared by dissolving 0.3 mM of N719™ dye (manufactured by Dyesol) in a solvent of acetonitrile/t-butanol=1/1, and the Ti foil substrate was immersed in this solution for 20 hours to form a porous layer. Thus, an oxide semiconductor electrode layer was produced. Subsequently, two sheets of this oxide semiconductor electrode layer were installed, at a distance of 10 mm, on a plastic substrate having a thickness of 100 μm.

(Production of Counter Electrode Layer)

Platinum was laminated by sputtering on an ITO film/PEN substrate (second electrode layer) having a thickness of 125 μm, so as to obtain a total light transmittance of 65%, and thus a catalyst layer was formed. The laminate was cut to a size of 50 mm×50 mm, and thus a counter electrode layer was formed. Subsequently, two sheets of this counter electrode layer were installed, at a distance of 10 mm, on a transparent plastic substrate having a thickness of 100 μm.

(Preparation of Resin Electrolyte Solution)

Dissolved were 6 mol/l of hexyl methylimidazolium iodide (manufactured by Tomiyama Pure Chemical Industries, Ltd.), 0.6 mol/1 of I₂ (manufactured by Merck KGaA), and 0.45 mol/l of n-methylbenzimidazole (manufactured by Sigma-Aldrich Corporation) in hexylmethylimidazolium tetracyanoborate (manufactured by Merck KGaA), and thus a Liquid electrolyte was prepared. Subsequently, a resin solution was prepared by dissolving STD-100™ (manufactured by Nisshin Kasei Kogyo Co., Ltd.) in ethanol in an amount of 10 wt %, and a resin electrolyte solution was prepared by mixing the liquid electrolyte with the resin solution at a ratio of liquid electrolyte:resin solution=1:6 (weight ratio).

(Production of Dye-Sensitized Solar Cell Module)

The resin electrolyte solution was applied on the porous layer of the oxide semiconductor electrode layer to a solid thickness of 100 μm, and the resin electrolyte solution was dried in an oven at 100° C. for 5 minutes to form a solid electrolyte layer. Subsequently, the solid electrolyte layer on the oxide semiconductor electrode layer and the catalyst layer of the counter electrode layer were arranged to face each other, and the first electrode layer and the second electrode layer were shifted horizontally by 10 mm and bonded together. The assembly was subjected to thermal lamination in a vacuum laminator, and thereby a dye-sensitized solar cell was produced.

Thereafter, a fixing member made of metal was disposed so as to vertically penetrate through the pair of plastic substrates, using a stapler, while the first electrode layer and the catalyst layer of the second electrode layer were separated apart. Thereby, the first electrode layer and the second electrode layer were connected together, and thereby the pairing resin substrates were fixed.

The takeoff portions on both sides were respectively connected to electrically conductive tapes that were installed outside, by disposing a fixing member made of metal thereon using a stapler in the same manner as described above.

### Example 2

(Production of Dye-Sensitized Solar Cell Module)

A dye-sensitized solar cell module was produced in the same manner as in Example 1, except that a fixing member made of metal was disposed so as to vertically penetrate through the pair of plastic substrates, using a stapler, while the first electrode layer and the catalyst layer of the second electrode layer of the dye-sensitized solar cell were in contact, and thereby the first electrode layer and the second electrode layer were connected to fix the pairing resin substrates.

[Evaluation]

As an evaluation of the performance of the dye-sensitized solar cell modules obtained in Example 1 and Example 2, the photoelectric conversion efficiency was measured. The measurement was made using spectrometer measurement system CEP-2000™, under the conditions of AM 1.5. The results are presented in Table 1. In Table 1, the term Jsc (mA/cm²) represents the short-circuit current density; Voc (V) represents the open-circuit voltage; FF represents the fill factor; and η (%) represents the photoelectric conversion efficiency.

TABLE 1

| | Jsc (mA/cm²) | Voc (V) | FF | η (%) |
|---|---|---|---|---|
| Example 1 | 3.3 | 1.42 | 0.63 | 2.9 |
| Example 2 | 6.5 | 1.42 | 0.63 | 5.8 |

When a fixing member was formed, a pair of resin substrates could be fixed, and thus a dye-sensitized solar cell module having high photoelectric conversion efficiency could be easily produced.

### Example 3

(Production of Porous Layer)

On a Ti foil substrate (manufactured by Etakeuchi Co., Ltd.) (metal layer) having a size of 50 mm×50 mm and a thickness of 50 μm, a paste prepared by mixing titanium oxide particles P25™ (manufactured by Nippon Aerosil Co. Ltd.) with 0.5% ethyl cellulose STD-100™ (manufactured by Nisshin Kasei Kogyo Co., Ltd.) in ethanol was applied at two sites, at a distance of 10 mm, in an application area of 50 mm×15 mm. Subsequently, the paste was dried in an oven at 120° C. for 10 minutes, and was burned at 500° C. for 30 minutes. Thus, a layer for porous layer formation was formed (thickness 5 μm). Subsequently, a liquid was prepared by dissolving 0.3 mM of N719 dye™ (manufactured by Dyesol) in a solvent of acetonitrile/t-butanol=1/1, and the Ti foil substrate was immersed in this solution for 20 hours to form a porous layer.

(Production of Catalyst Layer)

A film of platinum was formed by sputtering on an ITO/PEN substrate (transparent electrode layer and transparent resin substrate) having a thickness of 125 μm, at two sites each having an area of 50 mm×15 mm and separated at a distance of 10 mm, so as to obtain a total light transmittance of 65%. Thus, catalyst layers were formed.

(Preparation of Resin Electrolyte Solution)

Dissolved were 6 mol/l of hexyl methylimidazolium iodide (manufactured by Tomiyama Pure Chemical Industries, Ltd.), 0.6 mol/l of I₂ (manufactured by Merck KGaA), and 0.45 mol/l of n-methylbenzimidazole (manufactured by Sigma-Aldrich Corporation) in hexylmethylimidazolium tetracyanoborate (manufactured by Merck KGaA), and thus a liquid electrolyte was prepared. Subsequently, a resin solution was prepared by dissolving STD-100™ (manufactured by Nisshin Kasei Kogyo Co., Ltd.) in ethanol in an amount of 10 wt %, and a resin electrolyte solution was prepared by mixing the liquid electrolyte with the resin solution at a ratio of liquid electrolyte:resin solution=1:6 (weight ratio).

(Production of Dye-Sensitized Solar Cell Module)

The resin electrolyte solution was applied on the porous layer of the metal layer to a solid thickness of 5 μm, and the resin electrolyte solution was dried in an oven at 100° C. for 5 minutes to form a solid electrolyte layer. Subsequently, the solid electrolyte layer on the metal layer and the catalyst layer of the transparent resin substrate were arranged to face each other and were bonded together, and thus a dye-sensitized solar cell was obtained. The takeoff portions on both sides were respectively connected to electrically conductive tapes that were installed outside, by disposing a fixing member made of metal thereon using a stapler. Subsequently, the module was covered in the vertical direction using a thermoplastic transparent resin film, and the module was subjected to thermal lamination in a vacuum laminator. Subsequently, a fixing member made of a resin was disposed between adjacent dye-sensitized solar cells using a stapler, and the dye-sensitized solar cells were fixed in a manner such that the transparent electrode layer and the metal layer on the transparent resin substrate were not in contact. Thus, a dye-sensitized solar cell module was obtained.

### Example 4

A dye-sensitized solar cell module was obtained in the same manner as in Example 3, except that the catalyst layer and wiring were formed on the transparent electrode layer on the transparent resin substrate as shown below.

A film of platinum was formed by sputtering on an ITO/PEN substrate (transparent electrode layer and transparent resin substrate) having a thickness of 125 μm, at two sites each having an area of 50 mm×15 mm and separated at a distance of 10 mm, so as to obtain a total light transmittance of 65%. Thus, catalyst layers were formed. Furthermore, a Ag film was formed by screen printing at the site where the catalyst layers were not formed, in an area of 50 mm×8 mm, and thus wiring was formed between the two catalyst layers.

As an evaluation for the performance of the dye-sensitized solar cell module obtained in Example 3 and Example 4, the photoelectric conversion efficiency was measured. In regard to the measurement method, the same measurement method as that used in Example 1 and Example 2 was used. The results are presented in Table 2.

TABLE 2

| | Jsc (mA/cm²) | Voc (V) | FF | η (%) |
|---|---|---|---|---|
| Example 3 | 8.0 | 0.71 | 0.50 | 2.8 |
| Example 4 | 10 | 0.71 | 0.63 | 4.5 |

When a fixing member was used, the metal layer and the resin substrate could be fixed, and thus a dye-sensitized solar cell module having high photoelectric conversion efficiency could be easily produced.

### REFERENCE SIGNS LIST

1a, 1b Resin Substrate

1c Transparent Resin Substrate

1d Metal Layer

1e Electrode Layer Having Transparency

10 Dye-sensitized solar cell

11 First Electrode Layer

12 Porous Layer

21 Second Electrode Layer

22 Catalyst Layer

3 Electrolyte Layer

4 Fixing Member

n Fixing Unit

n′ External Linkage Fixing Unit

100 Dye-sensitized solar cell Module

1. A dye-sensitized solar cell module comprising:
a pair of resin substrates having flexibility; and
two or more dye-sensitized solar cells formed between the pair of resin substrates,
wherein a fixing member is disposed between adjacent dye-sensitized solar cells and the fixing member is formed so as to penetrate through from an external side of one of the resin substrates to an external side of the other resin substrate.

2. The dye-sensitized solar cell module according to claim 1, wherein each of the dye-sensitized solar cells comprises:
an oxide semiconductor electrode layer which includes a first electrode layer formed on a surface of one of the resin substrates, and a porous layer formed on the first electrode layer and containing a dye-sensitizer-supported fine particle of a metal oxide semiconductor;
a counter electrode layer which includes a second electrode layer formed on a surface of the other resin substrate, and a catalyst layer formed on the second electrode layer; and
an electrolyte layer provided between the porous layer and the catalyst layer and containing a redox couple,
wherein the adjacent dye-sensitized solar cells are formed such that the first electrode layer or the second electrode layer of one of the dye-sensitized solar cells formed on one of the resin substrates, and the first electrode layer or the second electrode layer of the other dye-sensitized solar cell formed on the other resin substrate face each other at least partially, and
the fixing member is formed between the first electrode layers, between the first electrode layer and the second electrode layer, or between the second electrode layers of the adjacent dye-sensitized solar cells, and fixes positions of the pair of resin substrates such that the electrode layers are in a positional relationship allowing connection between the electrode layers.

3. The dye-sensitized solar cell module according to claim 2, wherein, among the adjacent dye-sensitized solar cells, the first electrode layer of one of the dye-sensitized solar cells is formed on the surface of one of the resin substrate, while the second electrode layer of the other dye-sensitized solar cell is formed on the surface of the other resin substrate, and the fixing member fixes the positions of the pair of resin substrates such that the first electrode layer of one of the dye-sensitized solar cells and the second electrode layer of the other dye-sensitized solar cell are in a positional relationship allowing connection between the electrode layers.

4. The dye-sensitized solar cell module according to claim 1, wherein the fixing member is electrically conductive.

5. The dye-sensitized solar cell module according to claim 1, wherein the fixing member has insulating properties.

6. A dye-sensitized solar cell module comprising two or more dye-sensitized solar cells formed therein, each dye-sensitized solar cell having:
a metal layer having flexibility;
a transparent resin substrate having flexibility, and carrying an electrode layer having transparency formed on one surface of the transparent resin substrate;
a porous layer formed in a pattern on a surface of the metal layer or a surface of the electrode layer having transparency, and containing a dye-sensitizer-supported fine particle of a metal oxide semiconductor;
a catalyst layer formed on the surface of the metal layer or the surface of the electrode layer having transparency, where the porous layer is not formed; and
an electrolyte layer provided between the porous layer and the catalyst layer and containing a redox couple,
wherein a fixing member having insulating properties is disposed between adjacent dye-sensitized solar cells and the fixing member is formed so as to penetrate through from an external side of the metal layer to an external side of the transparent resin substrate.

7. The dye-sensitized solar cell module according to claim 1, wherein a thickness of a portion fixed by the fixing member is smaller than a thickness of a portion where the dye-sensitized solar cell is formed.

8. The dye-sensitized solar cell module according to claim 2, wherein a thickness of a portion fixed by the fixing member is smaller than a thickness of a portion where the dye-sensitized solar cell is formed.

9. The dye-sensitized solar cell module according to claim 6, wherein a thickness of a portion fixed by the fixing member is smaller than a thickness of a portion where the dye-sensitized solar cell is formed.

10. A method for producing a dye-sensitized solar cell module comprising a pair of resin substrates having flexibility, and at least two dye-sensitized solar cells formed between the pair of resin substrates, the method comprising steps of:
forming at least two dye-sensitized solar cells, each having
an oxide semiconductor electrode layer which includes a first electrode layer formed on a surface of one of the resin substrates, and a porous layer formed on the first electrode layer and containing a dye-sensitizer-supported fine particle of a metal oxide semiconductor,
a counter electrode layer which includes a second electrode layer formed on a surface of the other resin substrate, and a catalyst layer formed on the second electrode layer, and
an electrolyte layer provided between the porous layer and the catalyst layer and containing a redox couple; and
disposing a fixing member between adjacent dye-sensitized solar cells by forming the fixing member so as to penetrate through from an external side of one of the resin substrates to an external side of the other resin substrate.

11. A method for producing a dye-sensitized solar cell module, the method comprising steps of:
forming two or more dye-sensitized solar cells, each having
a metal layer having flexibility,
a transparent resin substrate having flexibility, and carrying an electrode layer having transparency formed on one surface of the transparent resin substrate,
a porous layer formed in a pattern on a surface of the metal layer or a surface of the electrode layer having transparency, and containing a dye-sensitizer-supported fine particle of a metal oxide semiconductor,
a catalyst layer formed on the surface of the metal layer or the surface of the electrode layer having transparency, where the porous layer is not formed, and
an electrolyte layer provided between the porous layer and the catalyst layer and containing a redox couple; and
disposing a fixing member having insulating properties between adjacent dye-sensitized solar cells, by forming the fixing member so as to penetrate through from an external side of the metal layer to an external side of the transparent resin substrate.
